(19) United States
(12) Patent Application Publication
(10) Pub. No.: US 2002/0171096 A1
(43) Pub. Date: Nov. 21, 2002

(54) Schottky gate field effect transistor with high output characteristic

(75) Inventors: Akio Wakejima, Tokyo (JP); Kazuki Ota, Tokyo (JP); Kohji Matsunaga, Tokyo (JP); Walter Contrata, Tokyo (JP); Masaaki Kuzuhara, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, Tokyo (JP)

(21) Appl. No.: 10/147,089

(22) Filed: May 17, 2002

(30) Foreign Application Priority Data
May 17, 2001 (JP) 2001-147526

(51) Int. Cl. H01L 29/80

(52) U.S. Cl. 257/280

(57) ABSTRACT

In a field effect transistor, there are provided a gate electrode on a Schottky layer over an InP channel layer over the substrate, and a field control electrode extending over an insulating layer and separated from the Schottky layer and being positioned between the gate electrode and the drain electrode for controlling an expansion of a space charge region in the channel layer.

### BACKGROUND OF THE INVENTION

1. Field of the Invention

The present invention relates to a semiconductor field effect transistor, and more particularly to a Schottky gate field effect transistor with a high frequency performance and a high output in a microwave range, which is suitable for various applications to mobile communications, satellite communications and satellite broadcasting.

2. Description of the Related Art

Compound semiconductors are attractive in utilizing high speed behaviors of electrons for applications to high frequency and high speed devices. In compound semiconductor field effect transistors, a gate electrode is provided in contact with a channel layer of a substrate or a Schottky layer thereof. This structure is likely to cause a field concentration at an edge of the electrode in a drain side. This field concentration may further cause a break-down or a current injection into the gate electrode, resulting in a deterioration of the high frequency performance. The deterioration of the high frequency performance is a serious problem with a field effect transistor designed for a high output amplifier. Some proposals for relaxing the field concentration at the drain-side edge of the gate electrode were made. An example of the conventional techniques for relaxing the field concentration is to provide a field control electrode over an insulating film between a gate and a drain, which is disclosed in Japanese laid-open patent publication No. 2000-3919, incorporated herein as a reference. Another example is to utilize a larger band gap InGaP for a channel layer, instead of GaAs and InGaAs, for ensuring a high field stability, which is disclosed in Japanese laid-open patent publication No. 10-261653, incorporated herein as another reference.

In the field effect transistor with the InGaP channel layer, the band gap of the InGaP channel layer is larger than GaAs-based compound semiconductor channel layer which has often be used in the prior art. The larger band gap of the InGaP channel layer is effective to relax the field concentration at the drain-side edge of the gate. This is effective to prevent the break-down or the gate leakage due to the field concentration, and thus the deterioration of the high frequency performance.

This conventional technique of using the larger band gap of the InGaP channel layer is, however, disadvantageous in that electron speed is relatively slow. This makes it difficult to take a large drain current, resulting in reduction in amplitude of the current and thus a difficulty in obtaining a high output.

In the above circumstances, the development of a novel field effect transistor free from the above problems is desirable.

### SUMMARY OF THE INVENTION

Accordingly, it is an object of the present invention to provide a novel field effect transistor free from the above problems.

It is a further object of the present invention to provide a novel field effect transistor with both a high withstand voltage characteristic and a high output current characteristic for high output performance.

The present invention provides a field effect transistor including: a substrate; a channel layer over the substrate, and the channel layer comprising a first compound semiconductor having a larger band gap than GaAs; a Schottky layer over the channel layer; a gate electrode having a Schottky junction with the Schottky layer; source and drain electrodes spatially distanced from each other and also from the gate electrode; an insulating layer extending over at least a first region of the Schottky layer, and the first region being positioned between the gate electrode and the drain electrode; and a field control electrode extending over the insulating layer and being separated from the Schottky layer, and the field control electrode being positioned between the gate electrode and the drain electrode for controlling a space charge region in the channel layer and under the at least first region.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a fragmentary cross sectional elevation view of the field effect transistor of the first preferred embodiment according to the present invention.

FIG. 2 is a fragmentary cross sectional elevation view of the field effect transistor of the second preferred embodiment according to the present invention.

FIG. 3 is a fragmentary cross sectional elevation view of the field effect transistor of the third preferred embodiment according to the present invention.

FIG. 4 is a fragmentary cross sectional elevation view of the field effect transistor of the fourth preferred embodiment according to the present invention.

FIG. 5 is a fragmentary cross sectional elevation view of the field effect transistor of the fifth preferred embodiment according to the present invention.

FIG. 6 is a fragmentary cross sectional elevation view of the field effect transistor of the sixth preferred embodiment according to the present invention.

FIG. 7 is a fragmentary cross sectional elevation view of the field effect transistor of the seventh preferred embodiment according to the present invention.

FIG. 8 is a fragmentary cross sectional elevation view of the field effect transistor of the eighth preferred embodiment according to the present invention.

FIG. 9 is a fragmentary cross sectional elevation view of the field effect transistor of the ninth preferred embodiment according to the present invention.

FIG. 10 is a fragmentary cross sectional elevation view of the field effect transistor of the tenth preferred embodiment according to the present invention.

FIG. 11 is a fragmentary cross sectional elevation view of the field effect transistor of the eleventh preferred embodiment according to the present invention.

FIG. 12 is a fragmentary cross sectional elevation view of the field Effect transistor of the twelfth preferred embodiment according to the present invention.

FIGS. 13A through 13G are fragmentary cross sectional elevation views illustrative of the field effect transistors in sequential steps involved in the novel method in accordance with the present invention.

FIG. 14A is a diagram showing respective maximum drain currents of the novel field effect transistor of Example 1 according to the present invention, as well as the first, second and third conventional field effect transistors of the first, second and third comparative examples.

FIG. 14B is a diagram showing respective gate withstand voltages of the novel field effect transistor of Example 1 according to the present invention, as well as the first, second and third conventional field effect transistors of the first, second and third comparative examples.

FIG. 14C is a diagram showing respective variations in output over drain voltage at a frequency of 2 GHz and a gate width of 1 millimeter of the novel field effect transistor of Example 1 according to the present invention, as well as the first, second and third conventional field effect transistors of the first, second and third comparative examples.

FIG. 14D is a diagram showing respectively estimated respective maximum drain currents in RF-operation of the novel field effect transistor of Example 1 according to the present invention, as well as the first, second and third conventional field effect transistors of the first, second and third comparative examples.

FIGS. 15A and 15B are fragmentary cross sectional elevation views illustrative of the field effect transistors in sequential steps involved in the novel method in accordance with the present invention.

FIG. 16A is a diagram illustrative of respective variations in output over the drain voltages of the first novel field effect transistor in Example 1 and the second novel field effect transistor in Example 2 in accordance with the present invention.

FIG. 16B is a diagram illustrative of respective variations in saturation output over frequencies of the first novel field effect transistor in Example 1 and the second novel field effect transistor in Example 2 in accordance with the present invention.

FIG. 16C is a diagram illustrative of respective variations in drain current over storing time at a high temperature of 300° C. in nitrogen atmosphere of the first novel field effect transistor in Example 1 and the second novel field effect transistor in Example 2 in accordance with the present invention.

FIGS. 17A and 17B are fragmentary cross sectional elevation views illustrative of the field effect transistors in sequential steps involved in the novel method in accordance with the present invention.

FIG. 18A is a diagram illustrative of respective maximum drain currents and withstand voltages of the third novel field effect transistor in Example 3 and the second novel field effect transistor in Example 2 in accordance with the present invention.

FIG. 18B is a diagram illustrative of respective variations in output over the drain voltages at a frequency of 2 GHz of the third novel field effect transistor in Example 3 and the second novel field effect transistor in Example 2 in accordance with the present invention.

FIGS. 19A and 19B are fragmentary cross sectional elevation views illustrative of the field effect transistors in sequential steps involved in the novel method in accordance with the present invention.

FIG. 20A is a diagram illustrative of respective maximum drain currents and withstand voltages of the fourth novel field effect transistor in Example 4 and the second novel field effect transistor in Example 2 in accordance with the present invention.

FIG. 20B is a diagram illustrative of respective variations in output over the drain voltages at a frequency of 2 GHz of the fourth novel field effect transistor in Example 4 and the second novel field effect transistor in Example 2 in accordance with the present invention.

FIG. 21 is a fragmentary cross sectional elevation view illustrative of the fifth novel field effect transistor of Example 5 according to the present invention.

FIG. 22A is a diagram illustrative of respective variations in drain current over a field control electrode voltage of the fifth novel field effect transistor in Example 5 according to the present invention and a fourth conventional field effect transistor as the fourth comparative example.

FIG. 22B is a diagram illustrative of respective variations in withstand voltage over field control electrode voltages of the fifth novel field effect transistor in Example 5 according to the present invention and the fourth conventional field effect transistor as the fourth comparative example.

FIG. 22C is a diagram illustrative of respective variations in output over drain voltages of the fifth novel field effect transistor in Example 5 according to the present invention and a fifth conventional field effect transistor as the fifth comparative example.

FIGS. 23A through 23E are fragmentary cross sectional elevation views illustrative of the field effect transistors in sequential steps involved in the novel method in accordance with the present invention.

FIG. 24 is a diagram illustrative of variations in the output over the extending width, or the lateral size, of the drain-side gate extension portion of the gate electrode of the sixth novel field effect transistor of Example 6 according to the present invention.

FIG. 25 is a fragmentary cross sectional elevation view of the conventional field effect transistor as comparative example.

FIG. 26 is a fragmentary cross sectional elevation view of the other conventional field effect transistor as comparative example.

FIG. 27 is a fragmentary cross sectional elevation view of the other conventional field effect transistor as comparative example.

### DETAILED DESCRIPTION OF THE PREFERRED EMBODIMENTS

A first aspect of the present invention is a field effect transistor including: a substrate; a channel layer over the substrate, and the channel layer comprising a first compound semiconductor having a larger band gap than GaAs; a Schottky layer over the channel layer; a gate electrode having a Schottky junction with the Schottky layer; source and drain electrodes spatially distanced from each other and also from the gate electrode; an insulating layer extending over at least a first region of the Schottky layer, and the first region being positioned between the gate electrode and the drain electrode; and a field control electrode extending over the insulating layer and being separated from the Schottky layer, and the field control electrode being positioned between the gate electrode and the drain electrode for controlling a space charge region in the channel layer and under the at least first region.

It is advantageously possible that the field control electrode is spatially distanced from and electrically isolated from the drain electrode.

It is advantageously possible that the field control electrode is spatially distanced from and electrically isolated from the gate electrode, so that the field control electrode is independent in potential from the gate electrode.

It is advantageously possible that the field control electrode is spatially distanced from and electrically coupled to the gate electrode, so that the field control electrode is dependent in potential on the gate electrode.

It is advantageously possible that the field control electrode comprises an extension portion of the gate electrode, and the extension portion extends from the gate electrode toward the drain electrode, so that the field control electrode depends in potential on the gate electrode. The extension portion may preferably have a horizontal size in a range of 0.5 micrometer to 2 micrometers in a direction parallel to a line connecting between the gate electrode and the drain electrode.

It is advantageously possible that the field control electrode is applied with a positive DC-voltage.

It is advantageously possible that the first compound semiconductor of the channel layer is InGaP. The Schottky layer may comprise an InGaP layer comprises an InGaP layer.

It is advantageously possible that the Schottky layer comprises an InGaP layer comprises a strained InGaP layer.

It is advantageously possible that the Schottky layer comprises an InGaP Slayer comprises an InAlGaP layer.

It is advantageously possible that the substrate comprises a GaAs substrate.

A second aspect of the present invention is a semiconductor device including: a substrate; a channel layer over the substrate, and the channel layer comprising a first compound semiconductor having a larger band gap than GaAs; a Schottky layer over the channel layer; a gate electrode having a Schottky junction with the Schottky layer; source and drain electrodes spatially distanced from each other and also from the gate electrode; and a field controller for controlling an expansion of a space charge region in the channel layer and between the gate electrode and the drain electrode.

It is advantageously possible that the field controller comprises a field control electrode electrically isolated by an insulating film from the Schottky layer, and being positioned between the gate electrode and the drain electrode.

It is advantageously possible that the field control electrode is spatially distanced from and electrically isolated from the drain electrode.

It is advantageously possible that the field control electrode is spatially distanced from and electrically isolated from the gate electrode, so that the field control electrode is independent in potential from the gate electrode.

It is advantageously possible that the field control electrode is spatially distanced from and electrically coupled to the gate electrode, so that the field control electrode is dependent in potential on the gate electrode.

It is advantageously possible that the field control electrode comprises an extension portion of the gate electrode, and the extension portion extends from the gate electrode toward the drain electrode, so that the field control electrode depends in potential on the gate electrode.

It is advantageously possible that the extension portion has a horizontal size in a range of 0.5 micrometer to 2 micrometers in a direction parallel to a line connecting between the gate electrode and the drain electrode.

It is advantageously possible that the field control electrode is applied with a positive DC-voltage.

It is advantageously possible that the first compound semiconductor of the channel layer is InGaP.

It is advantageously possible that the Schottky layer comprises an InGaP layer comprises an InGaP layer.

It is advantageously possible that the Schottky layer comprises an InGaP layer comprises a strained InGaP layer.

It is advantageously possible that the Schottky layer comprises an InGaP layer comprises an InAlGaP layer.

It is advantageously possible that the substrate comprises a GaAs substrate.

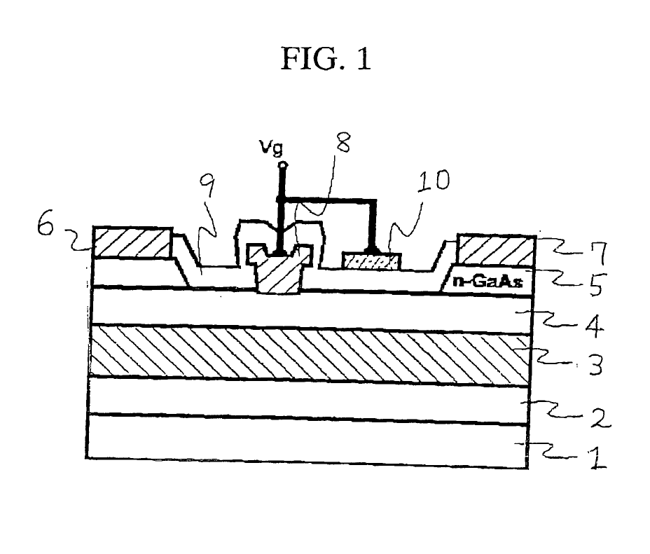

In a first preferred embodiment, a field effect transistor has a novel structure as shown in FIG. 1. FIG. 1 is a fragmentary cross sectional elevation view of the field effect transistor of the first preferred embodiment according to the present invention.

A buffer layer 2 is provided on a GaAs substrate 1. An n-InGaP layer 3 as a channel layer is provided on the buffer layer 2. A Schottky layer 4 is provided on the n-InGaP layer 3. Contact layers 5 are selectively provided on the Schottky layer 4. Source and drain electrodes 6 and 7 are provided on the contact layers 5. A gate electrode 8 is also selectively provided on the Schottky layer 4, so that the gate electrode 8 is distanced apart from the contact layers 5 and the source and drain electrodes 6 and 7. An insulating layer 9 is selectively provided on the Schottky layer 4 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7, but electrically coupled to the gate electrode 8, so that the field control electrode 10 is substantially the same DC-potential and substantially the same RF-potential and phase as the gate electrode 8.

An RF-signal is inputted into the gate electrode 8. When the potential of the gate electrode 8 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-outputs. InGaP has a band gap of about 1.9 eV which is larger than a band gap of about 1.4 eV of GaAs. This is advantageous for high voltage operation The n-InGaP layer 3 improves a high withstand voltage characteristic, while the field control electrode 10 improves the large current characteristic. The combination of the n-InGaP layer 3 and the field control electrode 10 improves the high output characteristic.

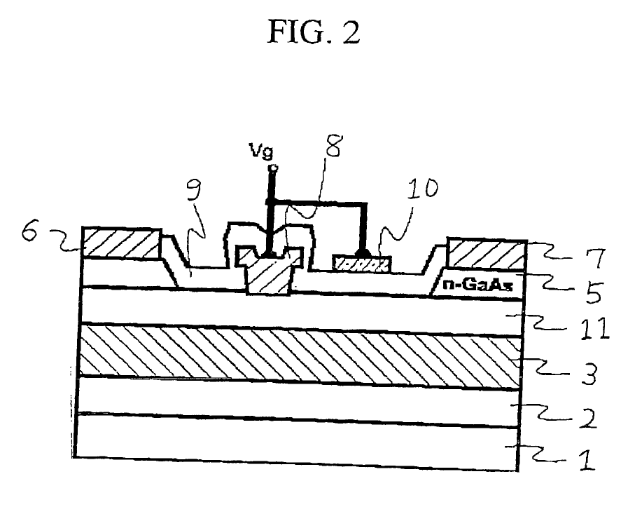

In a second preferred embodiment, a field effect transistor has a novel structure as shown in FIG. 2. FIG. 2 is a fragmentary cross sectional elevation view of the field effect transistor of the second preferred embodiment according to the present invention.

A buffer layer 2 is provided on a GaAs substrate 1. An n-InGaP layer 3 as a channel layer is provided on the buffer layer 2. An InGaP Schottky layer 11 is provided on the n-InGaP layer 3. Contact layers 5 are selectively provided on the InGaP Schottky layer 11. Source and drain electrodes 6 and 7 are provided on the contact layers 5. A gate electrode 8 is also selectively provided on the InGaP Schottky layer 11, so that the gate electrode 8 is distanced apart from the contact layers 5 and the source and drain electrodes 6 and 7. An insulating layer 9 is selectively provided on the InGaP Schottky layer 11 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7, but electrically coupled to the gate electrode 8, so that the field control electrode 10 is substantially the same DC-potential and substantially the same RF-potential and phase as the gate electrode 8.

An RF-signal is inputted into the gate electrode 8. When the potential of the gate electrode 8 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 cV of GaAs. This is advantageous for high voltage operation. The n-InGaP layer 3 improves a high withstand voltage characteristic, while the field control electrode 10 improves the large current characteristic. The combination of the n-InGaP layer 3 and the field control electrode 10 improves the high output characteristic.

Further, the InGaP Schottky layer 11 provides an advantages as follows. A surface of InGaP is stable, so that a interface state density between the InGaP Schottky layer 11 and the insulating layer 9 is extremely small. This results in a small delay in modulation to the space charge region under the field control electrode 10 from the inputted RF-signal, and thus a further improvement in the output characteristic as compared to when InGaP is used for only the channel layer as in the first preferred embodiment.

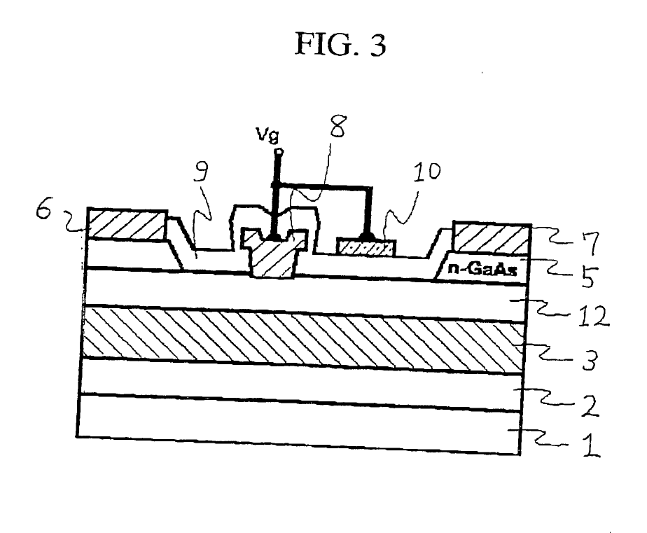

In a third preferred embodiment, a field effect transistor has a novel structure as shown in FIG. 3. FIG. 3 is a fragmentary cross sectional elevation view of the field effect transistor of the third preferred embodiment according to the present invention.

A buffer layer 2 is provided on a GaAs substrate 1. An n-InGaP layer 3 as a channel layer is provided on the buffer layer 2. A strained InGaP Schottky layer 12 having a smaller lattice constant than GaAs is provided on the n-InGaP layer 3. Contact layers 5 are selectively provided on the strained InGaP Schottky layer 12. Source and drain electrodes 6 and 7 are provided on the contact layers 5. A gate electrode 8 is also selectively provided on the strained InGaP Schottky layer 12, so that the gate electrode 8 is distanced apart from the contact layers 5 and the source and drain electrodes 6 and 7. An insulating layer 9 is selectively provided on the Strained InGaP Schottky layer 12 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7, but electrically coupled to the gate electrode 8, so that the field control electrode 10 is substantially the same DC-potential and substantially the same RF-potential and phase as the gate electrode 8.

An RF-signal is inputted into the gate electrode 8. When the potential of the gate electrode 8 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the field control electrode 10 improves the large current characteristic. The combination of the n-InGaP layer 3 and the field control electrode 10 improves the high output characteristic.

Further, the strained InGaP Schottky layer 12 provides an advantages as follows. Using strained InGaP for the Schottky layer improves the withstand voltage characteristic as compared to when InGaP lattice-matched to GaAs is used for the Schottky layer, resulting an improvement in stability to the break down due to the field concentration in the gate electrode edge in the drain side, and thus in the improvement of the high output characteristic.

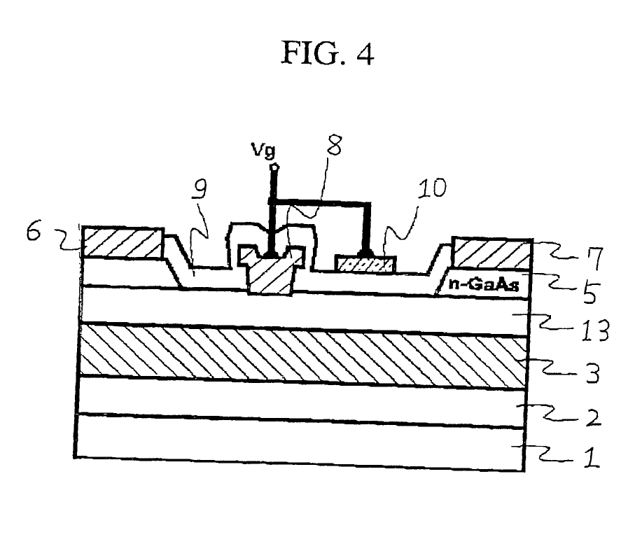

In a fourth preferred embodiment, a field effect transistor has a novel Structure as shown in FIG. 4. FIG. 4 is a fragmentary cross sectional elevation view of the field effect transistor of the fourth preferred embodiment according to the present invention.

A buffer layer 2 is provided on a GaAs substrate 1. An n-InGaP layer 3 as a channel layer is provided on the buffer layer 2. An InAlGaP Schottky layer 13 having a smaller lattice constant than GaAs is provided on the n-InGaP layer 3. Contact layers 5 are selectively provided on the InAlGaP Schottky layer 13. Source and drain electrodes 6 and 7 are provided on the contact layers 5. A gate electrode 8 is also selectively provided on the InAlGaP Schottky layer 13, so that the gate electrode 8 is distanced apart from the contact layers 5 and the source and drain electrodes 6 and 7. An insulating layer 9 is selectively provided on the InAlGaP Schottky layer 13 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7, but electrically coupled to the gate electrode 8, so that the field control electrode 10 is substantially the same DC-potential and substantially the same RF-potential and phase as the gate electrode 8.

An RF-signal is inputted into the gate electrode 8. When the potential of the gate electrode 8 becomes positive, a space charge region under the field control electrode 10 becomes small, because the drain current is increased and the current amplitude becomes large in the high output operation to improve the RP-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the field control electrode 10 improves the large current characteristic. The combination of the n-InGaP layer 3 and the field control electrode 10 improves the high output characteristic.

Further, the InAlGaP Schottky layer 13 provides an advantages as follows. Using InAlGaP for the Schottky layer improves the withstand voltage characteristic as compared to when InGaP lattice-matched to GaAs is used for the Schottky layer, resulting an improvement in stability to the break down due to the field concentration in the gate electrode edge in the drain side, and thus in the improvement of the high output characteristic.

Furthermore, InAlGaP of the InAlGaP Schottky layer 13 has a large band gap and is lattice-matched to GaAs. This eliminates any undesirable limitation to the thickness of the InAlGaP Schottky layer 13. This is advantageous for furthermore improve the higher output characteristic.

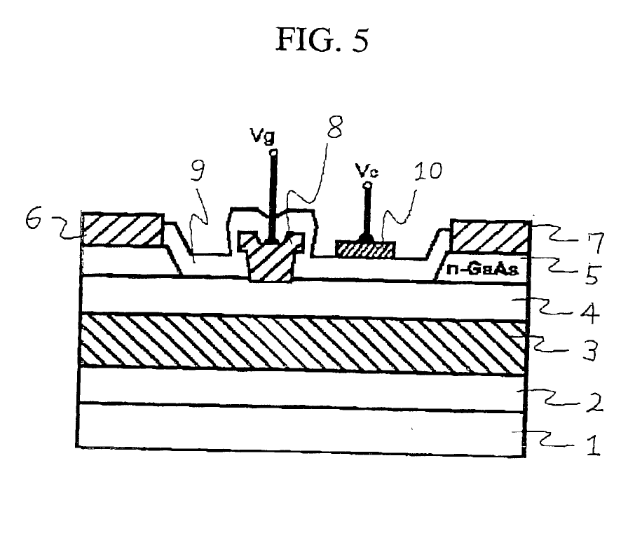

In a fifth preferred embodiment, a field effect transistor has a novel structure as shown in FIG. 5. FIG. 5 is a fragmentary cross sectional elevation view of the field effect transistor of the fifth preferred embodiment according to the present invention.

A buffer layer 2 is provided on a GaAs substrate 1. An n-InGaP layer 3 as a channel layer is provided on the buffer layer 2. A Schottky layer 4 is provided on the n-InGaP layer 3. Contact layers 5 are selectively provided on the Schottky layer 4. Source and drain electrodes 6 and 7 are provided on the contact layers 5. A gate electrode 8 is also selectively provided on the Schottky layer 4, so that the gate electrode 8 is distanced apart from the contact layers 5 and the source and drain electrodes 6 and 7. An insulating layer 9 is selectively provided on the Schottky layer 4 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7 and the gate electrode 8, so that the field control electrode 10 is independent in DC-potential, RF-potential and phase from the gate electrode 8.

A potential of the field control electrode 10 is kept positive or higher than zero. This may further increase the field concentration at the drain-side edge of the gate electrode 8. As described above, however, InGaP has a band gap of about 1.9 eV which is larger than a band gap of about 1.4 eV of GaAs. Therefore, the increase in the field concentration does not provide any large influence to the withstand voltage characteristic and also to the high voltage operation. When the potential of the field control electrode 10 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-output.

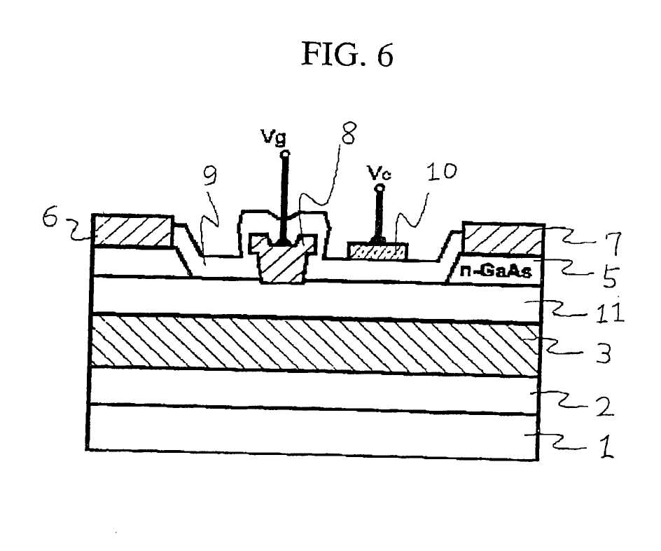

In a sixth preferred embodiment, a field effect transistor has a novel structure as shown in FIG. 6. FIG. 6 is a fragmentary cross sectional elevation view of the field effect transistor of the sixth preferred embodiment according to the present invention.

A buffer layer 2 is provided on a GaAs substrate 1. An n-InGaP layer 3 as a channel layer is provided on the buffer layer 2. An InGaP Schottky layer 11 is provided on the n-InGaP layer 3. Contact layers 5 are selectively provided on the InGaP Schottky layer 11. Source and drain electrodes 6 and 7 are provided on the contact layers 5. A gate electrode 8 is also selectively provided on the InGaP Schottky layer 11, so that the gate electrode 8 is distanced apart from the contact layers 5 and the source and drain electrodes 6 and 7. An insulating layer 9 is selectively provided on the InGaP Schottky layer 11 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7 and the gate electrode 8, so that the field control electrode 10 is independent in DC-potential, RF-potential and phase from the gate electrode 8.

A potential of the field control electrode 10 is kept positive or higher than zero. This may further increase the field concentration at the drain-side edge of the gate electrode 8. As described above, however, InGaP has a band gap of about 1.9 eV which is larger than a band gap of about 1.4 eV of GaAs. Therefore, the increase in the field concentration does not provide any large influence to the withstand voltage characteristic and also to the high voltage operation. When the potential of the field control electrode 10 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-output.

Further, the InGaP Schottky layer 11 provides an advantages as follows. A surface of InGaP is stable, so that a interface state density between the InGaP Schottky layer 11 and the insulating layer 9 is extremely small. This results in a small delay in modulation to the space charge region under the field control electrode 10 from the inputted RF-signal, and thus a further improvement in the output characteristic as compared to when InGaP is used for only the channel layer as in the fifth preferred embodiment.

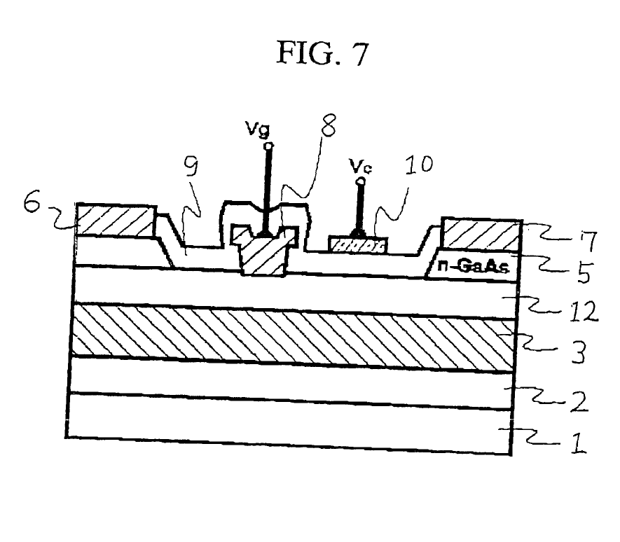

In a seventh preferred embodiment, a field effect transistor has a novel structure as shown in FIG. 7. FIG. 7 is a fragmentary cross sectional elevation view of the field effect transistor of the seventh preferred embodiment according to the present invention.

A buffer layer 2 is provided on a GaAs substrate 1. An n-InGaP layer 3 as a channel layer is provided on the buffer layer 2. A strained InGaP Schottky layer 12 having a smaller lattice constant than GaAs is provided on the n-InGaP layer 3. Contact layers 5 are selectively provided on the strained InGaP Schottky layer 12. Source and drain electrodes 6 and 7 are provided on the contact layers 5. A gate electrode 8 is also selectively provided on the strained InGaP Schottky layer 12, so that the gate electrode 8 is distanced apart from the contact layers 5 and the source and drain electrodes 6 and 7. An insulating layer 9 is selectively provided on the Strained InGaP Schottky layer 12 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7 and the gate electrode 8, so that the field control electrode 10 is independent in DC-potential, RF-potential and phase from the gate electrode 8.

A potential of the field control electrode 10 is kept positive or higher than zero. This may further increase the field concentration at the drain-side edge of the gate electrode 8. As described above, however, InGaP has a band gap of about 1.9 eV which is larger than a band gap of about 1.4 eV of GaAs. Therefore, the increase in the field concentration does not provide any large influence to the withstand voltage characteristic and also to the high voltage operation. When the potential of the field control electrode 10 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-output.

Further, the strained InGaP Schottky layer 12 provides an advantages as follows. Using strained InGaP for the Schottky layer improves the withstand voltage characteristic as compared to when InGaP lattice-matched to GaAs is used for the Schottky layer, resulting an improvement in stability to the break down due to the field concentration in the gate electrode edge in the drain side, and thus in the improvement of the high output characteristic.

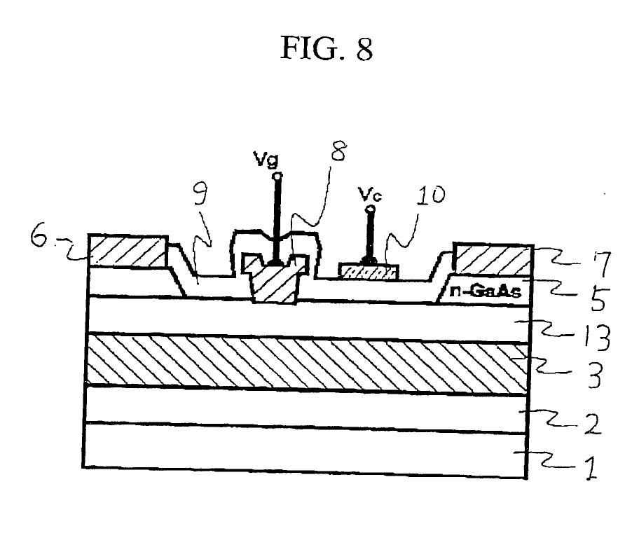

In an eighth preferred embodiment, a field effect transistor has a novel structure as shown in FIG. 8. FIG. 8 is a fragmentary cross sectional elevation view of the field effect transistor of the eighth preferred embodiment according to the present invention.

A buffer layer 2 is provided on a GaAs substrate 1. An n-InGaP layer 3 as a channel layer is provided on the buffer layer 2. An InAlGaP Schottky layer 13 having a smaller lattice constant than GaAs is provided on the n-InGaP layer 3. Contact layers 5 arc selectively provided on the InAlGaP Schottky layer 13. Source and drain electrodes 6 and 7 are provided on the contact layers 5. A gate electrode 8 is also selectively provided on the InAlGaP Schottky layer 13, so that the gate electrode 8 is distanced apart from the contact layers 5 and the source and drain electrodes 6 and 7. An insulating layer 9 is selectively provided on the InAlGaP Schottky layer 13 and over the gate electrode 8. A field control electrode 10 is selectively provided on the insulating layer 9 and positioned between the gate electrode 8 and the drain electrode 7, provided that the field control electrode 10 is spatially distanced and further electrically isolated from the drain electrode 7 and the gate electrode 8, so that the field control electrode 10 is independent in DC-potential, RF-potential and phase from the gate electrode 8.

A potential of the field control electrode 10 is kept positive or higher than zero. This may further increase the field concentration at the drain-side edge of the gate electrode 8. As described above, however, InGaP has a band gap of about 1.9 eV which is larger than a band gap of about 1.4 eV of GaAs. Therefore, the increase in the field concentration does not provide any large influence to the withstand voltage characteristic and also to the high voltage operation. When the potential of the field control electrode 10 becomes positive, a space charge region under the field control electrode 10 becomes small, because the drain current is increased and the current amplitude becomes large in the high output operation to improve the RF-output. Further, reduction to the RF-loss due to the resistive component in the drain side may improve the RF-output.

Further, the InAlGaP Schottky layer 13 provides an advantages as follows. Using InAlGaP for the Schottky layer improves the withstand voltage characteristic as compared to when InGaP lattice-matched to GaAs is used for the Schottky layer, resulting an improvement in stability to the break down due to the field concentration in the gate electrode edge in the drain side, and thus in the improvement of the high output characteristic.

Furthermore, InAlGaP of the InAlGaP Schottky layer 13 has a large band gap and is lattice-matched to GaAs. This eliminates any undesirable limitation to the thickness of the InAlGaP Schottky layer 13. This is advantageous for furthermore improve the higher output characteristic.

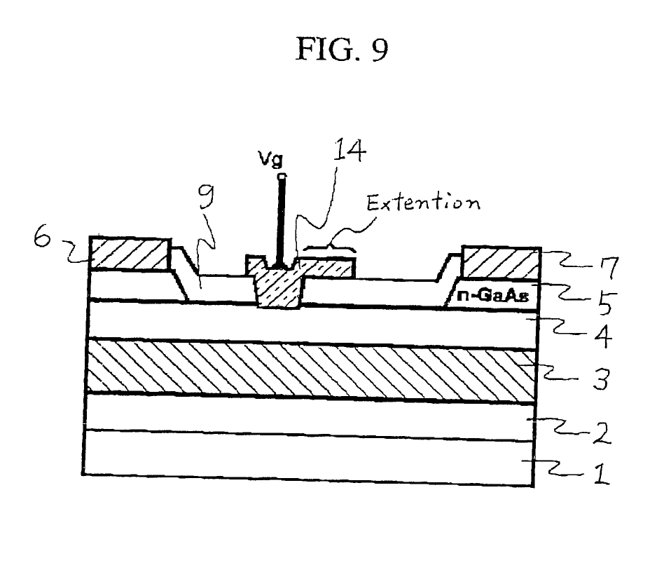

In a ninth preferred embodiment, a field effect transistor has a novel structure as shown in FIG. 9. FIG. 9 is a fragmentary cross sectional elevation view of the field effect transistor of the ninth preferred embodiment according to the present invention.

A buffer layer 2 is provided on a GaAs substrate 1. An n-InGaP layer 3 as a channel layer is provided on the buffer layer 2. A Schottky layer 4 is provided on the n-InGaP layer 3. Contact layers 5 are selectively provided on the Schottky layer 4. Source and drain electrodes 6 and 7 are provided on the contact layers 5. An insulating layer 9 is selectively provided on the Schottky layer 4. A gate electrode 8 including a drain-side gate extension portion is also selectively provided on the Schottky layer 4 and also over the insulating layer 9, so that the gate electrode 8 is distanced apart from the contact layers 5 and the source and drain electrodes 6 and 7. The drain-side gate extension portion of the gate electrode 8 extends over the insulating layer 9 but as distanced from the drain electrode. Of course, the drain-side gate extension portion has the same potential as inputted to the gate electrode 14.

The above-described drain-side gate extension portion of the gate electrode 14 serves as a field control electrode which is a part of the gate electrode 14. A space charge region under the drain-side gate extension portion serving as the field control electrode is so modulated as tuned with the modulation to the gate electrode 14. An RF-signal is inputted into the gate electrode 8. When the potential of the gate electrode 8 becomes positive, a space charge region under the drain-side gate extension portion serving as the field control electrode becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the drain-side gate extension portion serving as the field control electrode improves the large current characteristic The combination of the n-InGaP layer 3 and the drain-side gate extension portion serving as the field control electrode improves the high output characteristic.

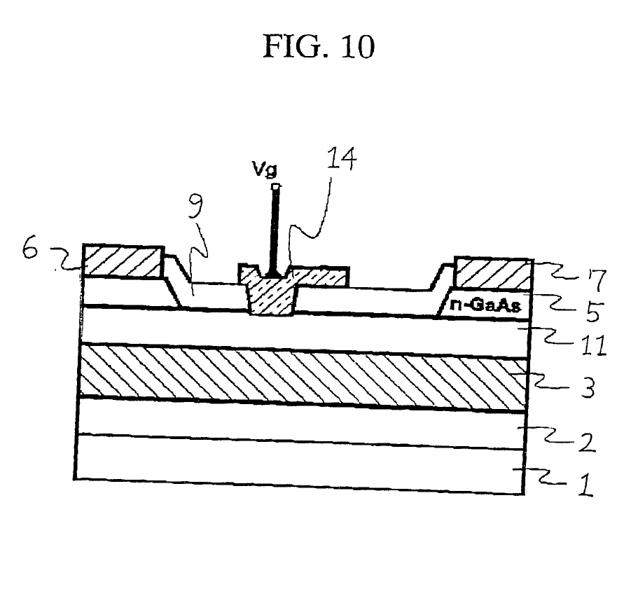

In a tenth preferred embodiment, a field effect transistor has a novel structure as shown in FIG. 10. FIG. 10 is a fragmentary cross sectional elevation view of the field effect transistor of the tenth preferred embodiment according to the present invention.

A buffer layer 2 is provided on a GaAs substrate 1. An n-InGaP layer 3 as a channel layer is provided on the buffer layer 2. An InGaP Schottky layer 11 is provided on the n-InGaP layer 3. Contact layers 5 are selectively provided on the InGaP Schottky layer 11. Source and drain electrodes 6 and 7 are provided on the contact layers 5. An insulating layer 9 is selectively provided on the Schottky layer 4. A gate electrode 8 including a drain-side gate extension portion is also selectively provided on the Schottky layer 4 and also over the insulating layer 9, so that the gate electrode 8 is distanced apart from the contact layers 5 and the source and drain electrodes 6 and 7. The drain-side gate extension portion of the gate electrode 8 extends over the insulating layer 9 but as distanced from the drain electrode. Of course, the drain-side gate extension portion has the same potential as inputted to the gate electrode 14.

The above-described drain-side gate extension portion of the gate electrode 14 serves as a field control electrode which is a part of the gate electrode 14. A space charge region under the drain-side gate extension portion serving as the field control electrode is so modulated as tuned with the modulation to the gate electrode 14. An RF-signal is inputted into the gate electrode 8. When the potential of the gate electrode 8 becomes positive, a space charge region under the drain-side gate extension portion serving as the field control electrode becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the drain-side gate extension portion serving as the field control electrode improves the large current characteristic. The combination of the n-InGaP layer 3 and the drain-side gate extension portion serving as the field control electrode improves the high output characteristic.

Further, the InGaP Schottky layer 11 provides an advantages as follows. A surface of InGaP is stable, so that a interface state density between the InGaP Schottky layer 11 and the insulating layer 9 is extremely small. This results in a small delay in modulation to the space charge region under the drain-side gate extension portion serving as the field control electrode from the inputted RF-signal, and thus a further improvement in the output characteristic as compared to when InGaP is used for only the channel layer as in the first preferred embodiment.

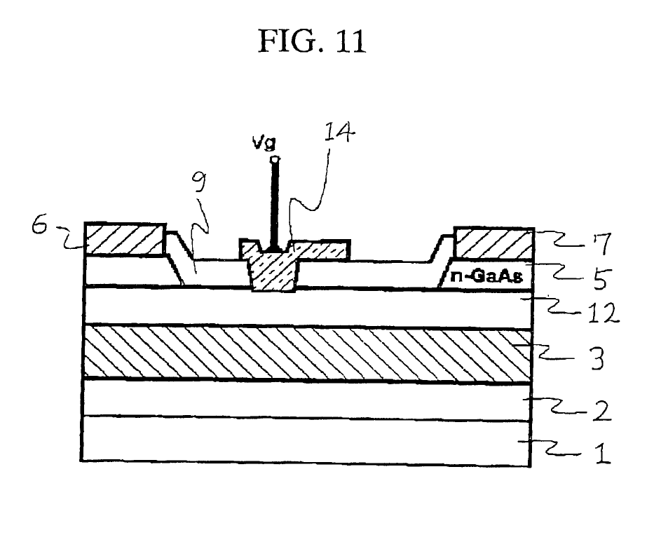

In an eleventh preferred embodiment, a field effect transistor has a novel structure as shown in FIG. 11. FIG. 11 is a fragmentary cross sectional elevation view of the field effect transistor of the eleventh preferred embodiment according to the present invention.

A buffer layer 2 is provided on a GaAs substrate 1. An n-InGaP layer 3 as a channel layer is provided on the buffer layer 2. A strained InGaP Schottky layer 12 having a smaller lattice constant than GaAs is provided on the n-InGaP layer 3. Contact layers 5 are selectively provided on the strained InGaP Schottky layer 12. Source and drain electrodes 6 and 7 are provided on the contact layers 5. An insulating layer 9 is selectively provided on the Schottky layer 4. A gate electrode 8 including a drain-side gate extension portion is also selectively provided on the Schottky layer 4 and also over the insulating layer 9, so that the gate electrode 8 is distanced apart from the contact layers 5 and the source and drain electrodes 6 and 7. The drain-side gate extension portion of the gate electrode 8 extends over the insulating layer 9 but as distanced from the drain electrode. Of course, the drain-side gate extension portion has the same potential as inputted to the gate electrode 14.

The above-described drain-side gate extension portion of the gate electrode 14 serves as a field control electrode which is a part of the gate electrode 14. A space charge region under the drain-side gate extension portion serving as the field control electrode is so modulated as tuned with the modulation to the gate electrode 14. An RF-signal is inputted into the gate electrode 8. When the potential of the gate electrode 8 becomes positive, a space charge region under the drain-side gate extension portion serving as the field control electrode becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the drain-side gate extension portion serving as the field control electrode improves the large current characteristic The combination of the n-InGaP layer 3 and the drain-side gate extension portion serving as the field control electrode improves the high output characteristic.

Further, the strained InGaP Schottky layer 12 provides an advantages as follows. Using strained InGaP for the Schottky layer improves the withstand voltage characteristic as compared to when InGaP lattice-matched to GaAs is used for the Schottky layer, resulting an improvement in stability to the break down due to the field concentration in the gate electrode edge in the drain side, and thus in the improvement of the high output characteristic.

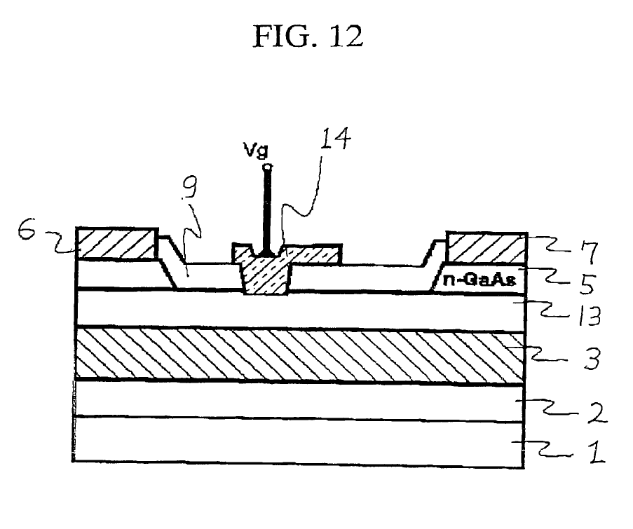

In a twelfth preferred embodiment, a field effect transistor has a novel structure as shown in FIG. 12. FIG. 12 is a fragmentary cross sectional elevation view of the field effect transistor of the twelfth preferred embodiment according to the present invention.

A buffer layer 2 is provided on a GaAs substrate 1. An n-InGaP layer 3 as a channel layer is provided on the buffer layer 2. An n-InAlGaP Schottky layer 13 having a smaller lattice constant than GaAs is provided on the n-InGaP layer 3. Contact layers 5 are selectively provided on the InAlGaP Schottky layer 13. Source and drain electrodes 6 and 7 are provided on the contact layers 5. An insulating layer 9 is selectively provided on the Schottky layer 4. A gate electrode 8 including a drain-side gate extension portion is also selectively provided on the Schottky layer 4 and also over the insulating layer 9, so that the gate electrode 8 is distanced apart from the contact layers 5 and the source and drain electrodes 6 and 7. The drain-side gate extension portion of the gate electrode 8 extends over the insulating layer 9 but as distanced from the drain electrode. Of course, the drain-side gate extension portion has the same potential as inputted to the gate electrode 14.

The above-described drain-side gate extension portion of the gate electrode 14 serves as a field control electrode which is a part of the gate electrode 14. A space charge region under the drain-side gate extension portion serving as the field control electrode is so modulated as tuned with the modulation to the gate electrode 14. An RF-signal is inputted into the gate electrode 8. When the potential of the gate electrode 8 becomes positive, a space charge region under the drain-side gate extension portion serving as the field control electrode becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the drain-side gate extension portion serving as the field control electrode improves the large current characteristic. The combination of the n-InGaP layer 3 and the drain-side gate extension portion serving as the field control electrode improves the high output characteristic.

Further, the InAlGaP Schottky layer 13 provides an advantages as follows. Using InAlGaP for the Schottky layer improves the withstand voltage characteristic as compared to when InGaP lattice-matched to GaAs is used for the Schottky layer, resulting an improvement in stability to the break down due to the field concentration in the gate electrode edge in the drain side, and thus in the improvement of the high output characteristic.

Furthermore, InAlGaP of the InAlGaP Schottky layer 13 has a large band gap and is lattice-matched to GaAs. This eliminates any undesirable limitation to the thickness of the InAlGaP Schottky layer 13. This is advantageous for furthermore improve the higher output characteristic.

### EXAMPLE 1

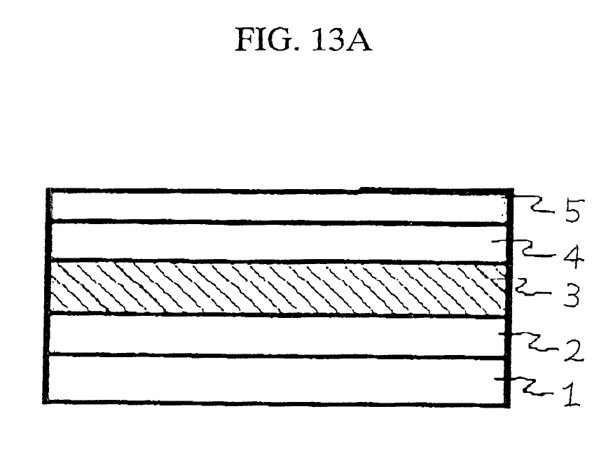

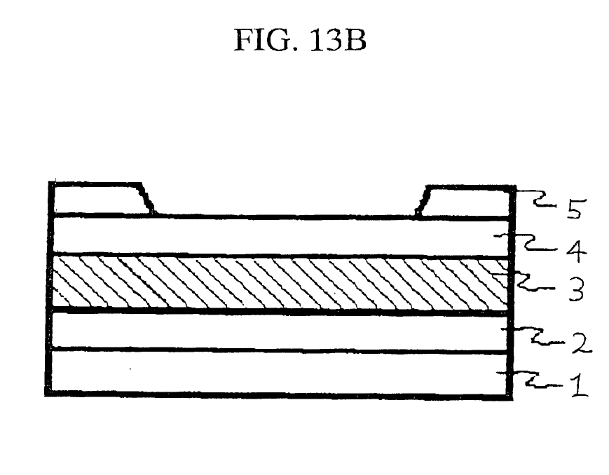

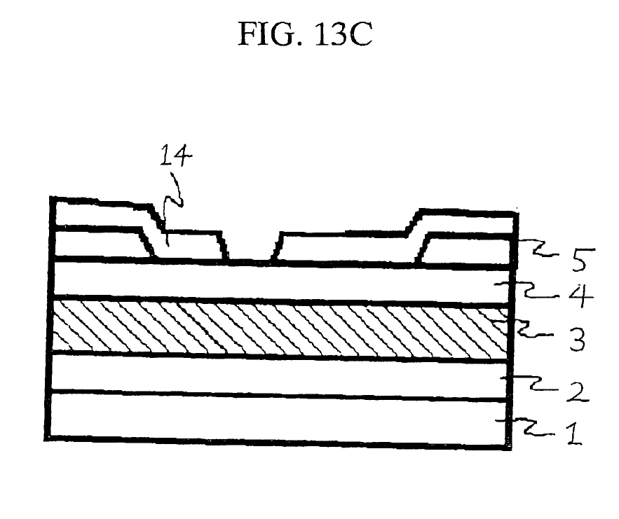

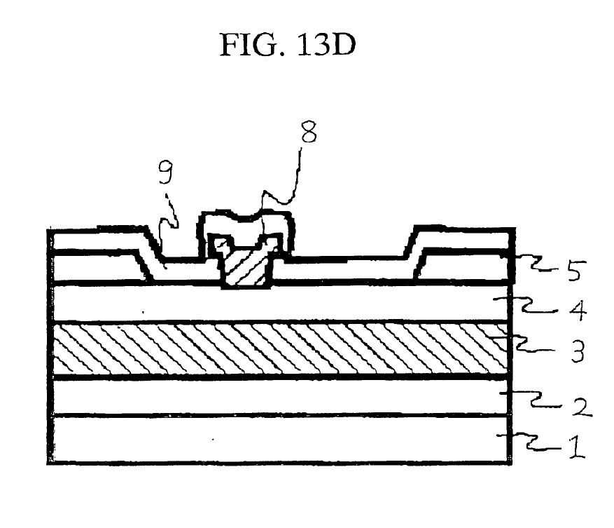

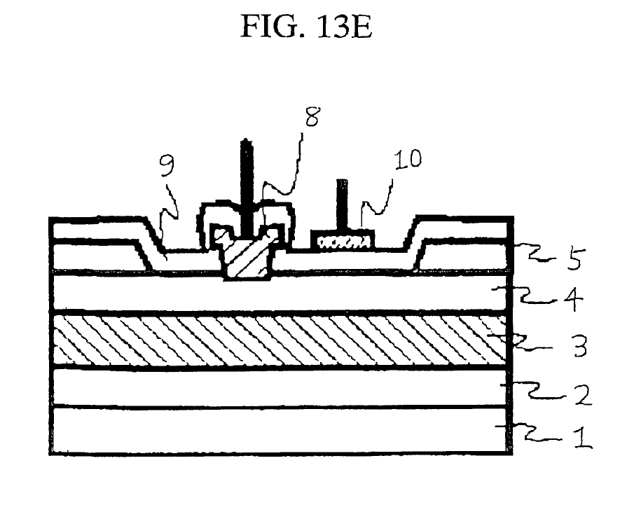

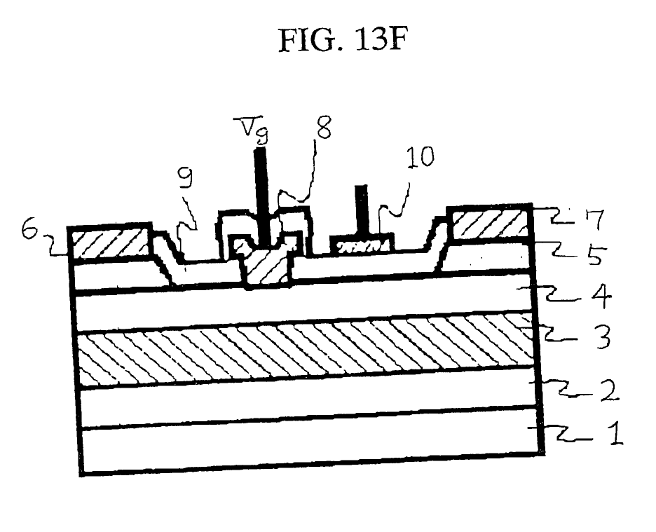

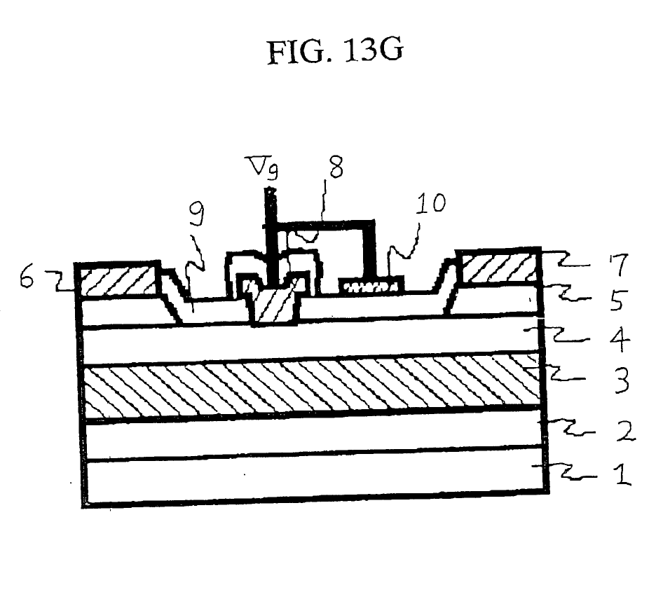

The above described first preferred embodiment will be described in more detail to enable a person skilled in the art to practice the invention in accordance with the first preferred embodiment. The field effect transistor described with reference to FIG. 1 in the first preferred embodiment may be formed as follows. FIGS. 13A through 13G are fragmentary cross sectional elevation views illustrative of the field effect transistors in sequential steps involved in the novel method in accordance with the present invention.

With reference to FIG. 13A, an AlGaAs buffer layer 2 was deposited by an MOCVD on a semi-insulating GaAs substrate 1. An n-InGaP layer 3, which is Si-doped at a doping concentration of 3E17 cm³ and has a thickness of 150 nanometers, was deposited by the MOCVD on the AlGaAs buffer layer 2. An AlGas Schottky layer 4 with a thickness of 20 nanometers was deposited by the MOCVD on the n-InGaP layer 3. An n-GaAs contact layer 5, which is Si-doped at a doping concentration of 3E17 cm⁻³ and has a thickness of 150 nanometers, was deposited by the MOCVD on the AlGaAs Schottky layer 4.

With reference to FIG. 13B, a resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

With reference to FIG. 13C, an SiO₂ insulating film 14 with a thickness of 300 nanometers was deposited by a CVD method over the n-GaAs contact layer 5 and an exposed surface of the AlGaAs Schottky layer 4. The SiO₂ insulating film 14 was then selectively etched by a dry etching process using SF6 to selectively form, in the SiO₂ insulating film 14, a recess through which a part of the surface of the AlGaAs Schottky layer 4 is exposed.

With reference to FIG. 13D, the AlGaAs Schottky layer 4 was then selectively etched at a shallow depth of approximately 5 nanometers by a dry etching process using the SiO₂ insulating film 14 including the recess as a mask. A WSi film of a thickness of 100 nanometers and an Au film of a thickness of 400 nanometers were sequentially deposited entirely by a sputtering method over the SiO₂ insulating film 14 and the exposed surface of the AlGaAs Schottky layer 4. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film 14 was also removed by a fluorine acid. Another SiO₂ insulating film 9 with a thickness of 100 nanometers was then deposited by the CVD method over the contact layers 5, the exposed surface of the AlGas Schottky layer 4 and the gate electrode 8.

With reference to FIG. 13E, a Ti film of a thickness of 100 nanometers and an Au film of a thickness of 500 nanometers were sequentially deposited entirely by a sputtering method over the SiO₂ insulating film 9. A resist pattern was selectively formed by a lithography technique over the Au film. The laminations of the Ti film and the Au film were selectively etched using the resist pattern as a mask, to selectively form a field control electrode 10, which is positioned between the gate electrode 8 and the drain electrode 7, provided that the field control electrode 10 is spatially distanced from them. The used resist pattern was removed.

With reference to FIG. 13F, the SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers.

With reference to FIG. 13G, finally, the gate electrode 8 and the field control electrode 10 were electrically connected through a TiAu wiring. The field effect transistor according to the present invention was completed, wherein a gate width is 1 millimeter.

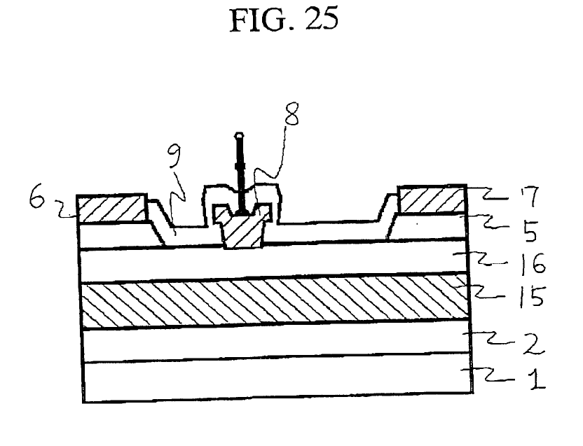

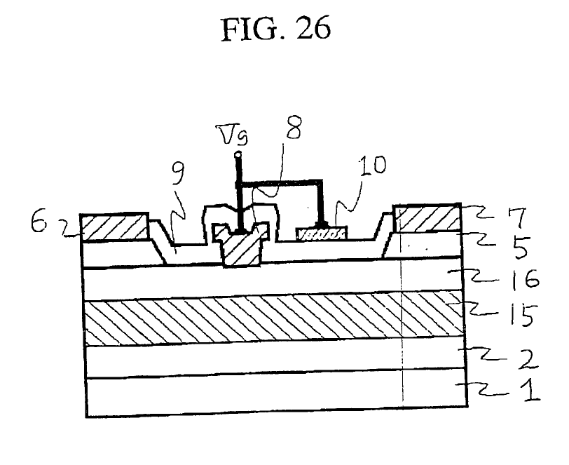

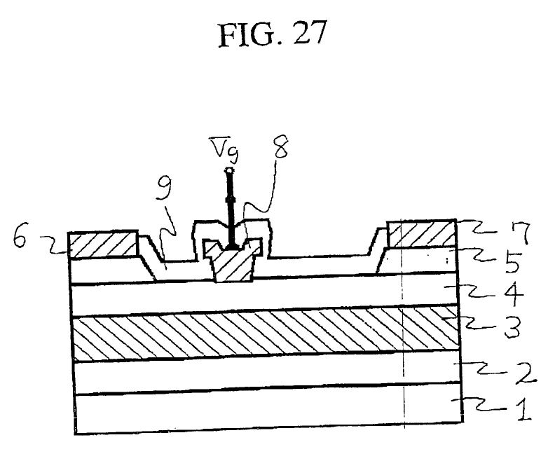

In order to evaluate the characteristic of the field effect transistor according to the present invention in compression with some conventional field effect transistors free of the field control electrodes. In a first comparative example, a first conventional field effect transistor free of the field control electrode was prepared, which will hereinafter be referred to as “first conventional field effect transistor” and also has a structure as shown; in FIG. 25. The first conventional field effect transistor is different from the novel field effect transistor in example 1 according to the present invention in that the channel layer comprises GaAs, and further the field control electrode is absent. In a second comparative example, a second conventional field effect transistor with the field control electrode was prepared, which will hereinafter be referred to as “second conventional field Effect transistor” and also has a structure as shown in FIG. 26. This second conventional field effect transistor is also disclosed in Japanese laid-open patent publication No. 2000-3919. The second conventional field effect transistor is different from the novel field effect transistor in example 1 according to the present invention in that the channel layer comprises GaAs. In a third comparative example, a third conventional field effect transistor free of the field control electrode was prepared, which will hereinafter be referred to as “third conventional field effect transistor” and also has a structure as shown in FIG. 27. This third conventional field effect transistor is also disclosed in Japanese laid-open patent publication No. 10-261653. The third conventional field effect transistor is different from the novel field effect transistor in example 1 according to the present invention in that the field control electrode is absent.

In the first comparative example, the first conventional field effect transistor free of the field control electrode shown in FIG. 25 was formed as follows.

An AlGaAs buffer layer 2 was deposited by an MOCVD on a semi Insulating GaAs substrate 1. An n-GaAs layer 15, which is Si-doped at a doping concentration of 2E17 cm⁻³ and has a thickness of 150 nanometers, was deposited by the MOCVD on the AlGaAs buffer layer 2. An AlGaAs Schottky layer 16 with a thickness of 20 nanometers was deposited by the MOCVD on the n-GaAs layer 15. An n-GaAs contact layer 5, which is Si-doped at a doping concentration of 3E17 cm⁻³ and has a thickness of 150 nanometers, was deposited by the MOCVD on the AlGaAs Schottky layer 16.

A resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film with a thickness of 300 nanometers was deposited by a CVD method over the n-GaAs contact layer 5 and an exposed surface of the AlGaAs Schottky layer 16. The SiO₂ insulating film was then selectively etched by a dry etching process using SF6 to selectively form, in the SiO₂ insulating film, a recess, through which a part of the surface of the AlGaAs Schottky layer 16 is exposed.

The AlGaAs Schottky layer 16 was then selectively etched at a shallow depth of approximately 5 nanometers by a dry etching process using the SiO₂ insulating film including the recess as a mask. A WSi film of a thickness of 100 nanometers and an Au film of a thickness of 400 nanometers were sequentially deposited entirely by a sputtering method over the SiO₂ insulating film 14 and the exposed surface of the AlGaAs Schottky layer 16. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film was also removed by a fluorine acid. Another SiO₂ insulating film 9 with a thickness of 100 nanometers was then deposited by the CVD method over the contact layers 5, the exposed surface of the AlGaAs Schottky layer 16 and the gate electrode 8.

The SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers. A gate width was 1 millimeter.

In the second comparative example, the second conventional field effect transistor with the field control electrode shown in FIG. 26 was formed as follows.

An AlGaAs buffer layer 2 was deposited by an MOCVD on a semi-insulating GaAs substrate 1. An n-GaAs layer 15, which is Si-doped at a doping concentration of 2E17 cm⁻³ and has a thickness of 150 nanometers, was deposited by the MOCVD on the AlGaAs buffer layer 2. An AlGaAs Schottky layer 16 with a thickness of 20 nanometers was deposited by the MOCVD on the n-GaAs layer 15. An n-GaAs contact layer 5, which is Si-doped at a doping concentration of 3E17 cm⁻³ and has a thickness of 150 nanometers, was deposited by the MOCVD on the AlGaAs Schottky layer 16.

A resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film with a thickness of 300 nanometers was deposited by a CVD method over the n-GaAs contact layer 5 and an exposed surface of the AlGaAs Schottky layer 16. The SiO₂ insulating film was then selectively etched by a dry etching process using SF6 to selectively form, in the SiO₂ insulating film, a recess, through which a part of the surface of the AlGaAs Schottky layer 16 is exposed.

The AlGaAs Schottky layer 16 was then selectively etched at a shallow depth of approximately 5 nanometers by a dry etching process using the SiO₂ insulating film including the recess as a mask A WSi film of a thickness of 100 nanometers and an Au film of a thickness of 400 nanometers were sequentially deposited entirely by a sputtering method over the SiO₂ insulating film 14 and the exposed surface of the AlGaAs Schottky layer 16. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film was also removed by a fluorine acid. Another SiO₂ insulating film 9 with a thickness of 100 nanometers was then deposited by the CVD method over the contact layers 5, the exposed surface of the AlGaAs Schottky layer 16 and the gate electrode 8.

A Ti film of a thickness of 100 nanometers and an Au film of a thickness of 500 nanometers were sequentially deposited entirely by a sputtering method over the SiO₂ insulating film 9. A resist pattern was selectively formed by a lithography technique over the Au film. The laminations of the Ti film and the Au film were selectively etched using the resist pattern as a mask, to selectively form a field control electrode 10, which is positioned between the gate electrode 8 and the drain electrode 7, provided that the field control electrode 10 is spatially distanced from them. The used resist pattern was removed.

The SiO₂ insulating film 9 was selectively etched, so that the surfaces of the contact layers 5 are exposed. Source and drain electrodes 6 and 71 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers.

Finally, the gate electrode 8 and the field control electrode 10 were electrically connected through a TiAu wiring. A gate width was 1 millimeter.

In the third comparative example, the third conventional field effect transistor free of the field control electrode shown in FIG. 27 was formed as follows.

An AlGaAs buffer layer 2 was deposited by an MOCVD on a semi-insulating GaAs substrate 1. An n-InGaP layer 3, which is Si-doped at a doping concentration of 3E17 cm⁻³ and has a thickness of 150 nanometers, was deposited by the MOCVD on the AlGaAs buffer layer 2. An AlGaAs Schottky layer 4 with a thickness of 20 nanometers was deposited by the MOCVD on the n-InGaP layer 3. An n-GaAs contact layer 5, which is Si-doped at a doping concentration of 3E17 cm⁻³ and has a thickness of 150 nanometers, was deposited by the MOCVD on the AlGaAs Schottky layer 4.

A resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film 14 with a thickness of 300 nanometers was deposited by a CVD method over the n-GaAs contact layer 5 and an exposed surface of the AlGaAs Schottky layer 4. The SiO₂ insulating film 14 was then selectively etched by a dry etching process using SF6 to selectively form, in the SiO₂ insulating film 14, a recess, through which a part of the surface of the AlGaAs Schottky layer 4 is exposed.

The AlGaAs Schottky layer 4 was then selectively etched at a shalldw depth of approximately 5 nanometers by a dry etching process using the SiO₂ insulating film 14 including the recess as a mask. A WSi film of a thickness of 100 nanometers and an Au film of a thickness of 400 nanometers were sequentially deposited entirely by a sputtering method over the SiO₂ insulating film 14 and the exposed surface of the AlGaAs Schottky layer 4. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film 14 was also removed by a fluorine acid. Another SiO₂ insulating film 9 with a thickness of 100 nanometers was then deposited by the CVD method over the contact layers 5, the exposed surface of the AlGaAs Schottky layer 4 and the gate electrode 8.

The SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers.

Finally, the gate electrode 8 and the field control electrode 10 were electrically connected through a TiAu wiring The third conventional field effect transistor was completed, wherein a gate width is 1 millimeter The above-described novel field effect transistor of Example 1 according to the present invention was compared in characteristics and performances to the above-described first, second and third conventional field effect transistors of the first, second and third comparative examples.

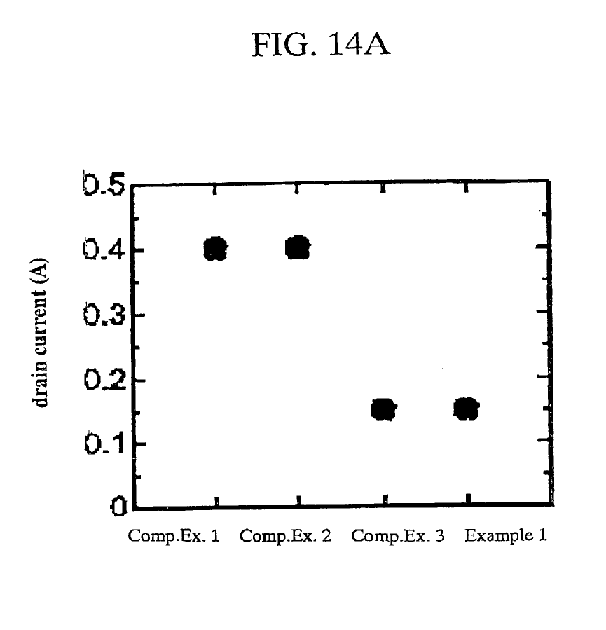

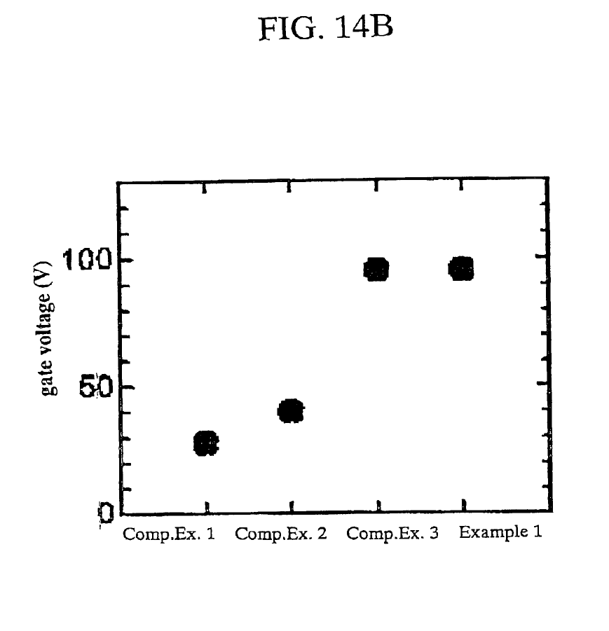

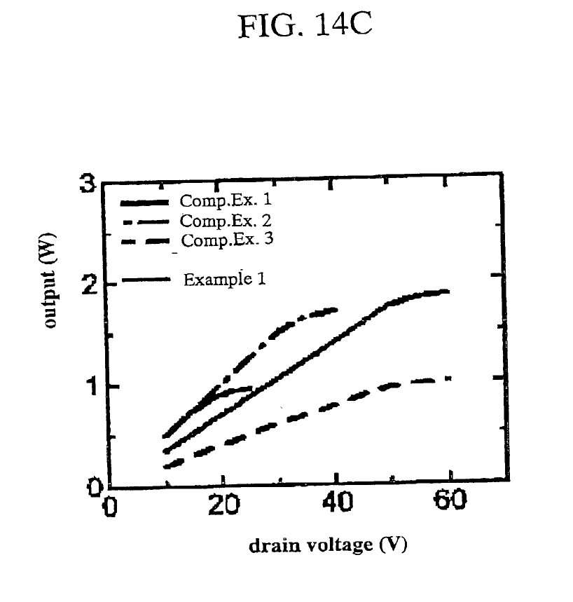

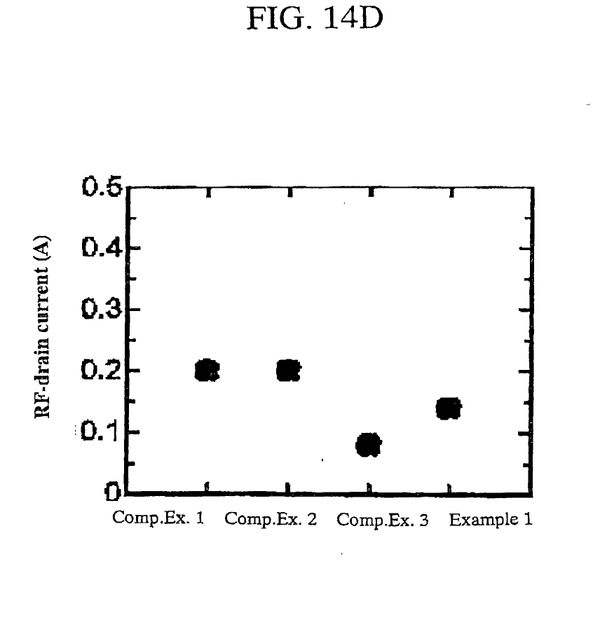

FIG. 14A is a diagram showing respective maximum drain currents of the novel field effect transistor of Example 1 according to the present invention, as well as the first, second and third conventional field effect transistors of the first, second and third comparative examples. “Comp.Ex.1” represents the first conventional field effect transistor of the first comparative example. “Comp.Ex.2” represents the second conventional field effect transistor of the second comparative example. “Comp.Ex.3” represents the third conventional field effect transistor of the third comparative example. “Ex.1” represents the novel field effect transistor of Example 1 according to the present invention.

It was confirmed that the first and second conventional field effect transistors exhibit relatively high maximum drain currents, while the third conventional field effect transistor and the novel field effect transistor of Example 1 exhibit relatively low maximum drain currents. This demonstrates that for InGaP-based compound semiconductor field effect transistor, the drain current is likely to be low, and it is difficult to take a large current amplitude in the RF-operation, and thus difficult to obtain a high output characteristic.

FIG. 14B is a diagram showing respective gate withstand voltages of the novel field effect transistor of Example 1 according to the present invention, as well as the first, second and third conventional field effect transistors of the first, second and third comparative examples. “Comp.Ex.1” represents the first conventional field effect transistor of the first comparative example. “Comp.Ex.2” represents the second conventional field effect transistor of the second comparative example. “Comp.Ex.3” represents the third conventional field effect transistor of the third comparative example. “Ex.1” represents the novel field effect transistor of Example 1 according to the present invention.

It was confirmed that the first and second conventional field effect transistors exhibit relatively low gate withstand voltages, while the third conventional field effect transistor and the novel field effect transistor of Example 1 exhibit relatively high gate withstand voltages. This demonstrates that for InGaP-based compound semiconductor field effect transistor, the gate withstand voltage is likely to be high because of the wide band gap of InGaP-based compound semiconductor.

Further, the first conventional GaAs field effect transistor free of the field control electrode is lower in the gate withstand voltage than the second GaAs conventional field effect transistor with the field control electrode, whilst the third conventional InGaP field effect transistor free of the field control electrode is approximately the same in the gate withstand voltage as the novel InGaP field effect transistor with the field control electrode. These demonstrate that in the GaAs-based field effect transistor, the field control electrode improves the gate withstand voltage characteristic, while in the InGaP-based field effect transistor, the gate withstand voltage characteristic is almost independent from the issue of presence or absence of the field control electrode.

FIG. 14C is a diagram showing respective variations in output over drain voltage at a frequency of 2 GHz and a gate width of 1 millimeter of the novel field effect transistor of Example 1 according to the present invention, as well as the first, second and third conventional field effect transistors of the first, second and third comparative examples. “Comp.Ex.1” represents the first conventional field effect transistor of the first comparative example. “Comp.Ex.2” represents the second conventional field effect transistor of the second comparative example. “Comp.Ex.3” represents the third conventional field effect transistor of the third comparative example. “Ex.1” represents the novel field effect transistor of Example 1 according to the present invention.

It was confirmed that the first and second conventional GaAs field effect transistors exhibit approximately the same output in a relatively low drain voltage range of 10V to 15V. As the drain voltage becomes higher than 15V and reaches 20V, the first conventional GaAs field effect transistor free of the field control electrode is generally saturated, while the second conventional GaAs field effect transistor with the field control electrode is not saturated yet and exhibits a further increase in the output with the increase of the drain voltage. This demonstrates that for GaAs-based compound semiconductor field effect transistor, the field control electrode improves the withstand voltage and allow operations at the high drain voltage, resulting in the high output characteristic.

It was also confirmed that the third conventional InGaP-based compound semiconductor field effect transistor free of the field control electrode remains remarkably lower in the output than the novel InGaP-based compound semiconductor field effect transistor with the field control electrode over the entire region of the drain voltages. This remarkable difference in output is caused by the presence and absence of the field control electrode. As the drain voltage increases, the difference in output becomes more remarkable, provided that the saturation voltage is independent from the presence and absence of the field control electrode.

Accordingly, in the InGaP field effect transistor, the presence of the field control electrode is not so effective to improve the withstand voltage characteristics, but is effective to increase the current amplitude in the RF-frequency operation, resulting in the improvement in the output. The presence of the field control electrode in the InGaP field effect transistor is more effective to improve the output characteristic as compared to the presence of the field control electrode of the GaAs field effect transistor.

In order to demonstrate the above estimations, from the respective output characteristics shown in FIG. 14C, estimations were made for the respective maximum drain currents in RF-operation of the novel field effect transistor of Example 1 according to the present invention, as well as the first, second and third conventional field effect transistors of the first, second and third comparative examples. FIG. 14D is a diagram showing respectively estimated respective maximum drain currents in RF-operation of the novel field effect transistor of Example 1 according to the present invention, as well as the first, second and third conventional field effect transistors of the first, second land third comparative examples.

It was confirmed that in the first and second conventional GaAs field effect transistors, the maximum drain current in RF-operation is almost independent from the presence and absence of the field control electrode, while in the third conventional and the novel InGaP field effect transistors, the presence of the field control electrode increases the maximum drain current in RF-operation.

### EXAMPLE 2

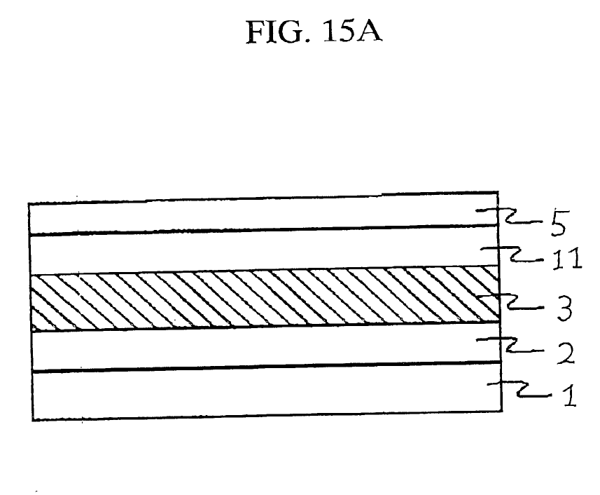

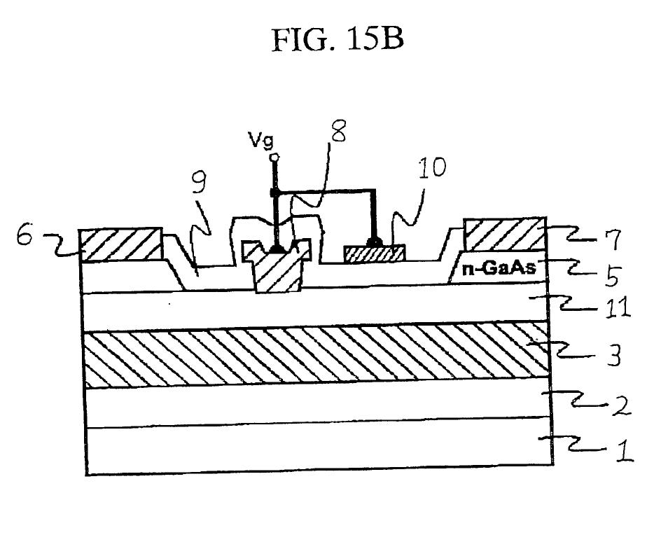

The above described second preferred embodiment will be described in more detail to enable a person skilled in the art to practice the invention in accordance with the second preferred embodiment. The field effect transistor described with reference to FIG. 2 in the second preferred embodiment may be formed as follows. FIGS. 15A and 15B are fragmentary cross sectional elevation views illustrative of the field effect transistors in sequential steps involved in the novel method in accordance with the present invention.

With reference to FIG. 15A, an AlGaAs buffer layer 2 was deposited by an MOCVD on a semi-insulating GaAs substrate 1. An n-InGaP layer 3, which is Si-doped at a doping concentration of 3E17 cm⁻³ and has a thickness of 150 nanometers, was deposited by the MOCVD on the AlGaAs buffer layer 2. An InGaAs Schottky layer 11 with a thickness of 20 nanometers was deposited by the MOCVD on the n-InGaP layer 3. An n-GaAs contact layer 5, which is Si-doped at a doping concentration of 3E17 cm⁻³ and has a thickness of 150 nanometers, was deposited by the MOCVD on the InGaAs Schottky layer 11.

With reference to FIG. 15B, a resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film 14 with a thickness of 300 nanometers was deposited by a CVD method over the n-GaAs contact layer 5 and an exposed surface of the InGaAs Schottky layer 11. The SiO₂ insulating film 14 was then selectively etched by a dry etching process using SF6 to selectively form, in the SiO₂ insulating film 14, a recess, through which a part of the surface of the InGaAs Schottky layer 11 is exposed.

The InGaAs Schottky layer 11 was then selectively etched at a shallow depth of approximately 5 nanometers by a dry etching process using the SiO₂ insulating film 14 including the recess as a mask. A WSi film of a thickness of 100 nanometers and an Au film of a thickness of 400 nanometers were sequentially deposited entirely by a sputtering method over the SiO₂ insulating film 14 and the exposed surface of the InGaAs Schottky layer 11. A resist pattern was selectively formed by a lithography technique over the Au film. The laminations of the WSi film and the Au film were selectively etched by an ion-milling using the resist pattern as a masks to selectively form a gate electrode 8. The used resist pattern was removed and the SiO₂ insulating film 14 was also removed by a fluorine acid. Another SiO₂ insulating film 9 with a thickness of 100 nanometers was then deposited by the CVD method over the contact layers 5, the exposed surface of the InGaAs Schottky layer 11 and the gate electrode 8.

A Ti film of a thickness of 100 nanometers and an Au film of a thickness of 500 nanometers were sequentially deposited entirely by a sputtering method over the SiO₂ insulating film 9. A resist pattern was selectively formed by a lithography technique over the Au film. The laminations of the Ti film and the Au film were selectively etched using the resist pattern as a mask, to selectively form a field control electrode 10, which is positioned between the gate electrode 8 and the drain electrode 7, provided that the field control electrode 10 is spatially distanced from them. The used resist pattern was removed.

The SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers.

Finally, the gate electrode 8 and the field control electrode 10 were electrically connected through a TiAu wiring. The field effect transistor according to the present invention was completed, wherein a gate width is 1 millimeter.

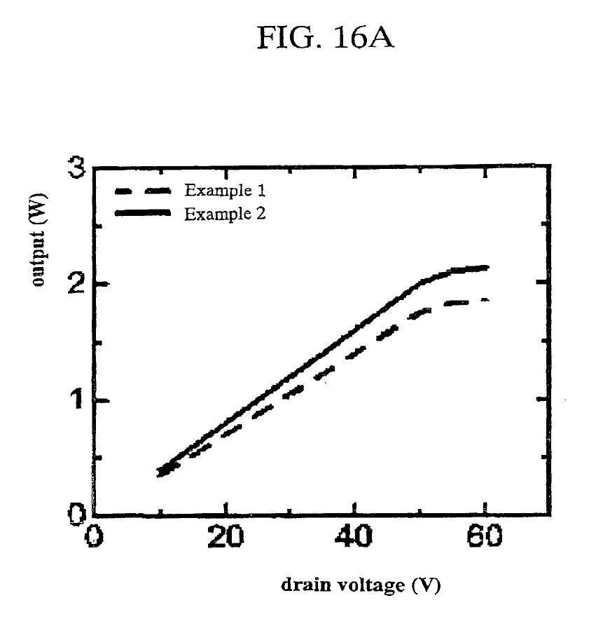

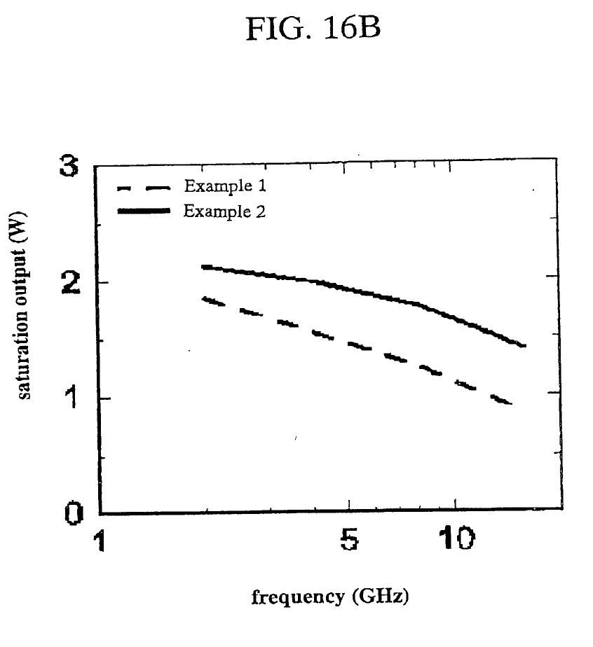

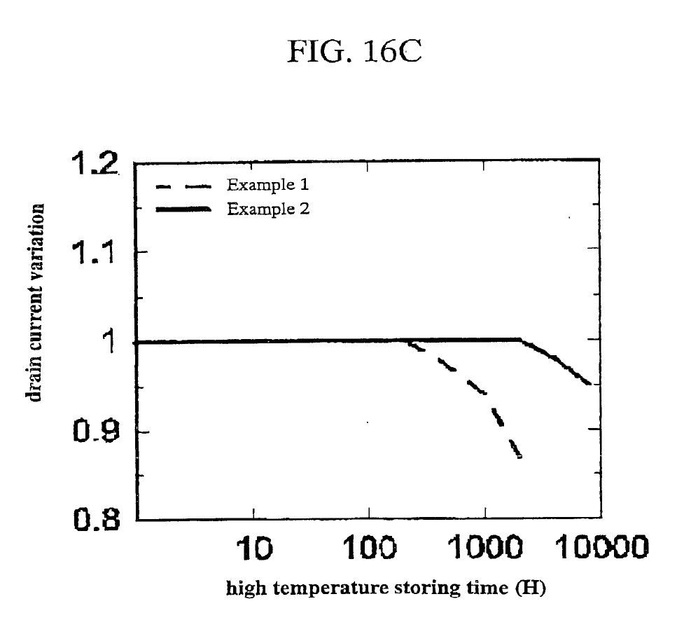

FIG. 16A is a diagram illustrative of respective variations in output over the drain voltages of the first novel field effect transistor in Example 1 and the second novel field effect transistor in Example 2 in accordance with the present invention. The broken line represents the variation in output over the drain voltage of the first novel field effect transistor in Example 1, while the real line represents the variation in output over the drain voltage of the second novel field effect transistor in Example 2. It was confirmed that the second novel field effect transistor in Example 2 is higher in output performance by about 15% than the first novel field effect transistor in Example 1.

It was also confirmed that the second novel field effect transistor in Example 2 exhibits almost the same DC drain current characteristic and almost the same withstand voltage characteristic as compared to the first novel field effect transistor in Example 1.

FIG. 16B is a diagram illustrative of respective variations in saturation output over frequencies of the first novel field effect transistor in Example 1 and the second novel field effect transistor in Example 2 in accordance with the present invention. The broken line represents the variation in saturation output over frequencies of the first novel field effect transistor in Example 1, while the real line represents the variation in saturation output over frequencies of the second novel field effect transistor in Example 2. It was confirmed that the second novel field effect transistor in Example 2 is kept higher in saturation output over frequencies as compared to the first novel field effect transistor in Example 1. In the second novel field effect transistor in Example 2, the Schottky layer 11 contacting with the insulating film 9 is free of aluminum, for which reason the interface state density between the aluminum-free Schottky layer 11 and the insulating film 9 in Example 2 is lower than the interface state density between the aluminum-containing Schottky layer 4 and the insulating film 9 in Example 1. This implies that the interface between the aluminum-free Schottky layer 11 and the insulating film 9 in Example 2 is more stable than the interface between the aluminum-containing Schottky layer 4 and the insulating film 9 in Example 1. This is because the second novel field effect transistor in Example 2 is kept higher in saturation output over frequencies as compared to the first novel field effect transistor in Example 1.

FIG. 16C is a diagram illustrative of respective variations in drain current over storing time at a high temperature of 300° C. in nitrogen atmosphere of the first novel field effect transistor in Example 1 and the second novel field effect transistor in Example 2 in accordance with the present invention. The broken line represents the variation in drain current over storing time of the first novel field effect transistor in Example 1, while the real line represents the variation in drain current over storing time of the second novel field effect transistor in Example 2. It was confirmed that the second novel field effect transistor in Example 2 exhibits no drop in the drain current even after 1000 hours at a high temperature of 300° C. in nitrogen atmosphere, while the first novel field effect transistor in Example 1 exhibits a large or remarkable drop in the drain current at 1000 hours. In the second novel field effect transistor in Example 2, the Schottky layer 11 is free of aluminum, while in the first novel field effect transistor in Example 1, the Schottky layer 4 contains aluminum. The aluminum-free Schottky layer 11 in the second novel field effect transistor in Example 2 is free from oxidation of aluminum, while the aluminum-containing Schottky layer 4 in the first novel field effect transistor in Example 1 may be subjected to oxidation of aluminum.

The above-described effects and advantages of the second novel field effect transistor in Example 2 may be obtained by modifications, as long as the InGaP layer is directly contact with the bottom surface of the insulating layer, on which the field control gate electrode is provided.

### EXAMPLE 3

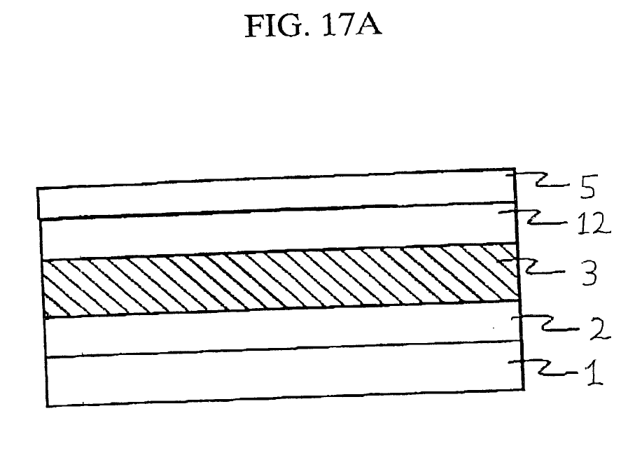

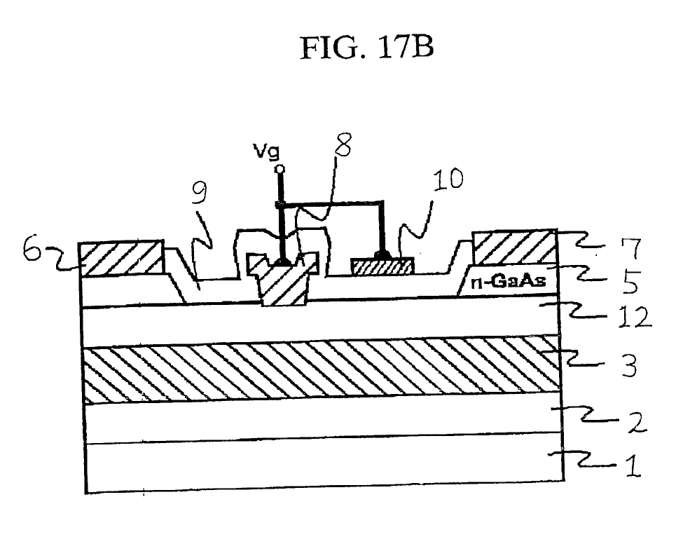

The above described third preferred embodiment will be described in more detail to enable a person skilled in the art to practice the invention in accordance with the third preferred embodiment. The field effect transistor described with reference to FIG. 3 in the third preferred embodiment may be formed as follows. FIGS. 17A and 17B are fragmentary cross sectional elevation views illustrative of the field effect transistors in sequential steps involved in the novel method in accordance with the present invention.

With reference to FIG. 17A, an AlGaAs buffer layer 2 was deposited by an MOCVD on a semi-insulating GaAs substrate 1. An n-InGaP layer 3, which is Si-doped at a doping concentration of 3E17 cm⁻³ and has a thickness of 150 nanometers, was deposited by the MOCVD on the AlGaAs buffer layer 2. A strained In_{0.4}Ga_{0.6}P Schottky layer 12 with a thickness of 20 nanometers was deposited by the MOCVD on the n-InGaP layer 3. An n-GaAs contact layer 5, which is Si-doped at a doping concentration of 3E17 cm⁻³ and has a thickness of 150 nanometers, was deposited by the MOCVD on the strained In_{0.4}Ga_{0.6}P Schottky layer 12.

With reference to FIG. 17B, a resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film 14 with a thickness of 300 nanometers was deposited by a CVD method over the n-GaAs contact layer 5 and an exposed surface of the strained In_{0.4}Ga_{0.6}P Schottky layer 12. The SiO₂ insulating film 14 was then selectively etched by a dry etching process using SF6 to selectively form, in the SiO₂ insulating film 14, a recess, through which a part of the surface of the strained In_{0.4}Ga_{0.6}P Schottky layer 12 is exposed.

The strained In_{0.4}Ga_{0.6}P Schottky layer 12 was then selectively etched at a shallow depth of approximately 5 nanometers by a dry etching process using the SiO₂ insulating film 14 including the recess as a mask. A WSi film of a thickness of 100 nanometers and an Au film of a thickness of 400 nanometers were sequentially deposited entirely by a sputtering method over the SiO₂ insulating film 14 and the exposed surface of the strained In_{0.4}Ga_{0.6}P Schottky layer 12. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film 14 was also removed by a fluorine acid. Another SiO₂ insulating film 9 with a thickness of 100 nanometers was then deposited by the CVD method over the contact layers 5, the exposed surface of the strained In_{0.4}Ga_{0.6}P Schottky layer 12 and the gate electrode 8.

A Ti film of a thickness of 100 nanometers and an Au film of a thickness of 500 nanometers were sequentially deposited entirely by a sputtering method over the SiO₂ insulating film 9. A resist pattern was selectively formed by a lithography technique over the Au film. The laminations of the Ti film and the Au film were selectively etched using the resist pattern as a mask, to selectively form a field control electrode 10, which is positioned between the gate electrode 8 and the drain electrode 7, provided that the field control electrode 10 is spatially distanced from them. The used resist pattern was removed.

The SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers.

Finally, the gate electrode 8 and the field control electrode 10 were electrically connected through a TiAu wiring. The field effect transistor according to the present invention was completed, wherein a gate width is 1 millimeter.

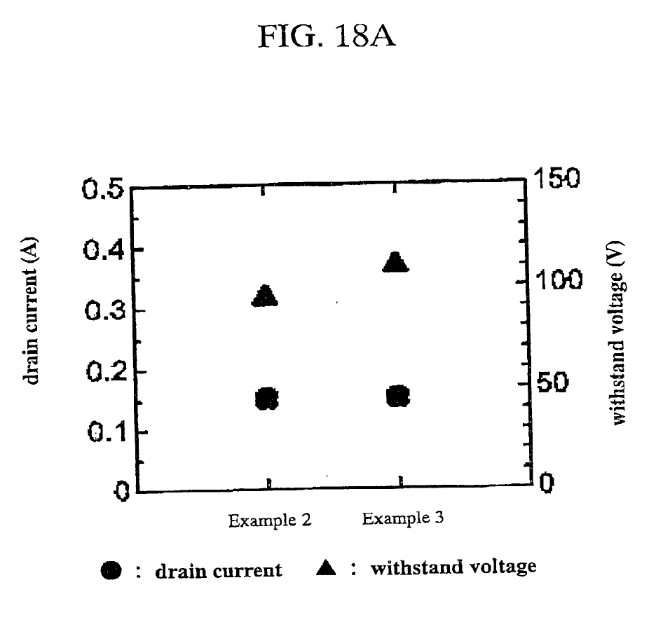

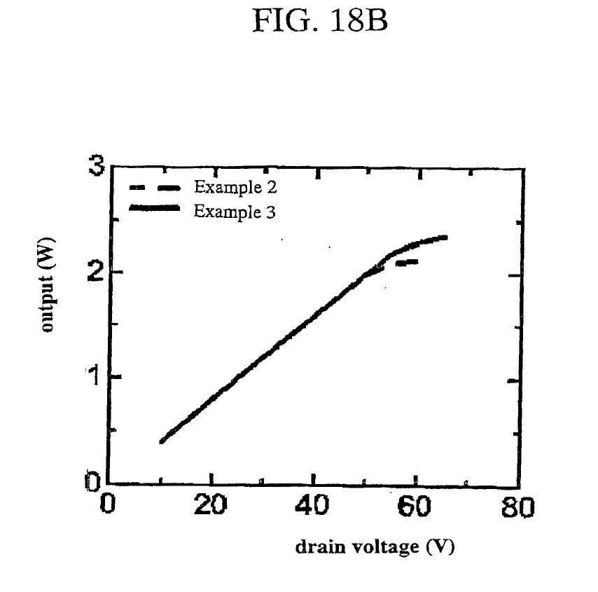

FIG. 18A is a diagram illustrative of respective maximum drain currents and withstand voltages of the third novel field effect transistor in Example 3 and the second novel field effect transistor in Example 2 in accordance with the present invention. ● represents the maximum drain current, while ▴ represents withstand voltage. It was confirmed that the third novel field effect transistor in Example 3 exhibits almost the same maxim um drain current as compared to the second novel field effect transistor in Example 2, while the third novel field effect transistor in Example 3 exhibits a higher withstand voltage by about 15% as compared to the second novel field effect transistor in Example 2.

FIG. 18B is a diagram illustrative of respective variations in output over the drain voltages at a frequency of 2 GHz of the third novel field effect transistor in Example 3 and the second novel field effect transistor in Example 2 in accordance with the present invention. The broken line represents the variation in output over the drain voltage of the second novel field effect transistor in Example 2, while the real line represents the variation in output over the drain voltage of the third novel field effect transistor in Example 3. It was confirmed that the second novel field effect transistor in Example 2 exhibits an output saturation at a drain voltage of about 55V, while the third novel field effect transistor in Example 3 exhibits an output saturation at a higher drain voltage of about 60V and also that the third novel field effect transistor in Example 3 is higher in maximum output by about 10% than the second novel field effect transistor in Example 2. Further, it was confirmed that the third novel field effect transistor in Example 3 exhibits almost the same output as the second novel field effect transistor in Example 2 in the drain voltage range of not high than 50V. This means that the third novel field effect transistor in Example 3 exhibits almost the same drain current amplitude in RF-operation as the second novel field effect transistor in Example 2.

The above-described effects and advantages of the third novel field effect transistor in Example 3 may be obtained by modifications, as long as the strained InGaP layer is directly contact with the bottom surface of the insulating layer, on which the field control gate electrode is provided.

### EXAMPLE 4

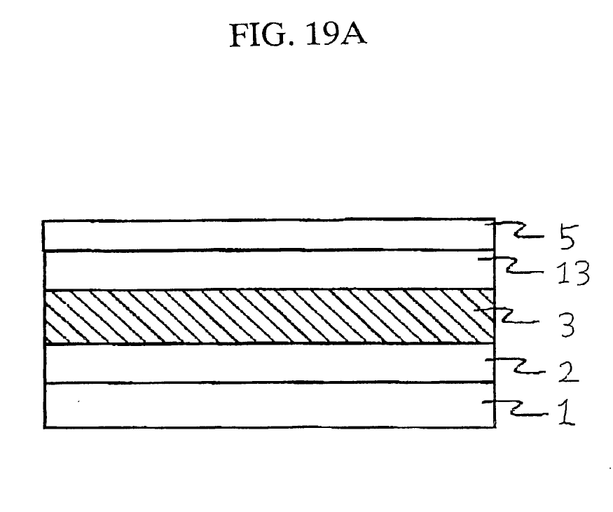

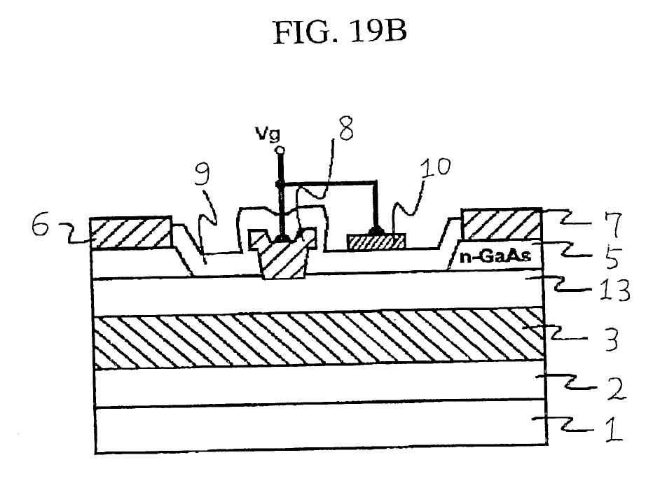

The above described fourth preferred embodiment will be described in more detail to enable a person skilled in the art to practice the invention in accordance with the fourth preferred embodiment. The field effect transistor described with reference to FIG. 4 in the fourth preferred embodiment may be formed as follows. FIGS. 19A and 19B are fragmentary cross sectional elevation views illustrative of the field effect transistors in sequential steps involved in the novel method in accordance with the present invention.

With reference to FIG. 19A, an AlGaAs buffer layer 2 was deposited by an MOCVD on a semi-insulating GaAs substrate 1. An n-InGaP layer 3, which is Si-doped at a doping concentration of 3E17 cm⁻³ and has a thickness of 150 nanometers, was deposited by the MOCVD on the AlGaAs buffer layer 2. An In_{0.5}Al_{0.4}Ga_{0.1}P Schottky layer 13 with a thickness of 20 nanometers was deposited by the MOCVD on the n-InGaP layer 3. An n-GaAs contact layer 5, which is Si-doped at a doping concentration of 3E17 cm⁻³ and has a thickness of 150 nanometers, was deposited by the MOCVD on the In_{0.5}Al_{0.4}Ga_{0.1}P Schottky layer 13.

With reference to FIG. 19B, a resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film 14 with a thickness of 300 nanometers was deposited by a CVD method over the n-GaAs contact layer 5 and an exposed surface of the In_{0.5}Al_{0.4}Ga_{0.1}P Schottky layer 13. The SiO₂ insulating film 14 was then selectively etched by a dry etching process using SF6 to selectively form, in the SiO₂ insulating film 14, a recess, through which a part of the surface of the In_{0.5}Al_{0.4}Ga_{0.1}P Schottky layer 13 is exposed.

The In_{0.5}Al_{0.4}Ga_{0.1}P Schottky layer 13 was then selectively etched at a shallow depth of approximately 5 nanometers by a dry etching process using the SiO₂ insulating film 14 including the recess as a mask. A WSi film of a thickness of 100 nanometers and an Au film of a thickness of 400 nanometers were sequentially deposited entirely by a sputtering method over the SiO₂ insulating film 14 and the exposed surface of the In_{0.5}Al_{0.4}Ga_{0.1}P Schottky layer 13. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film 14 was also removed by a fluorine acid. Another SiO₂ insulating film 9 with a thickness of 100 nanometers was then deposited by the CVD method over the contact layers 5, the exposed surface of the In_{0.5}Al_{0.4}Ga_{0.1}P Schottky layer 13 and the gate electrode 8.

A Ti film of a thickness of 100 nanometers and an Au film of a thickness of 500 nanometers were sequentially deposited entirely by a sputtering method over the SiO₂ insulating film 9. A resist pattern was selectively formed by a lithography technique over the Au film. The laminations of the Ti film and the Au film were selectively etched using the resist pattern as a mask, to selectively form a field control electrode 10, which is positioned between the gate electrode 8 and the drain electrode 7, provided that the field control electrode 10 is spatially distanced from them. The used resist pattern was removed.

The SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers.

Finally, the gate electrode 8 and the field control electrode 10 were electrically connected through a TiAu wiring. The field effect transistor according to the present invention was completed, wherein a gate width is 1 millimeter.

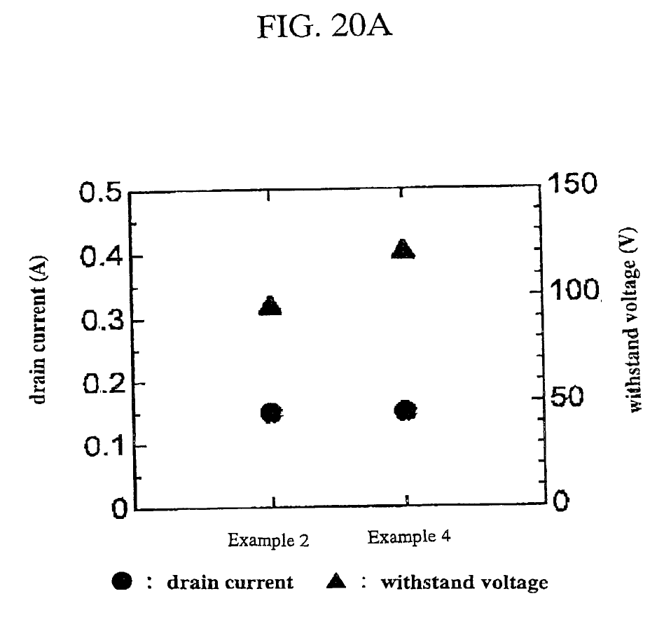

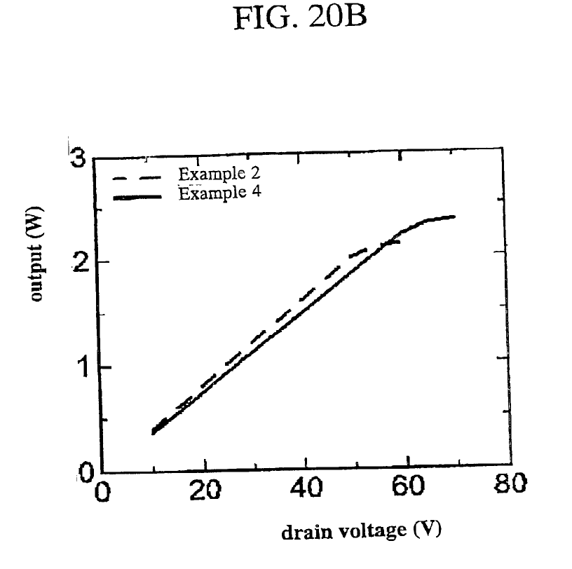

FIG. 20A is a diagram illustrative of respective maximum drain currents and withstand voltages of the fourth novel field effect transistor in Example 4 and the second novel field effect transistor in Example 2 in accordance with the present invention. ● represents the maximum drain current, while ▴ represents withstand voltage. It was confirmed that the fourth novel field effect transistor in Example 4 exhibits almost the same maximum drain current as compared to the second novel field effect transistor in Example 2, while the fourth novel field effect transistor in Example 4 exhibits a higher withstand voltage by about 25V than the second novel field effect transistor in Example 2.

FIG. 20B is a diagram illustrative of respective variations in output over the drain voltages at a frequency of 2 GHz of the fourth novel field effect transistor in Example 4 and the second novel field effect transistor in Example 2 in accordance with the present invention. The broken line represents the variation in output over the drain voltage of the second novel field effect transistor in Example 2, while the real line represents the variation in output over the drain voltage of the fourth novel field effect transistor in Example 4. It was confirmed that the second novel field effect transistor in Example 2 exhibits an output saturation at a drain voltage of about 55V, while the fourth novel field effect transistor in Example 4 exhibits an output saturation at a higher drain voltage of about 65V, and also that the fourth novel field effect transistor in Example 4 is higher in maximum output by about 15% than the second novel field effect transistor in Example 2.

The InAlGaP layer as the Schottky layer is directly contact with the bottom surface of the insulating layer, on which the field control electrode is provided, for which reason the interface state density between the InAlGaP Schottky layer and the insulating layer in Example 4 is higher than the interface state density between the InGaP Schottky layer and the insulating layer in Example 2. Namely, the interface stability between the InAlGaP Schottky layer and the insulating layer in Example 4 is lower than the interface stability between the InGaP Schottky layer and the insulating layer in Example 2. The InAlGaP Schottky layer is lattice-matched and allows an increase in thickness thereof. The increase in the thickness of the Schottky layer increases the withstand voltage. This thick InAlGaP Schottky layer is advantageous in the high withstand voltage.

The above-described effects and advantages of the fourth novel field effect transistor in Example 4 may be obtained by modifications, as long as the InAlGaP layer is directly contact with the bottom surface of the insulating layer, on which the field control gate electrode is provided.

### EXAMPLE 5

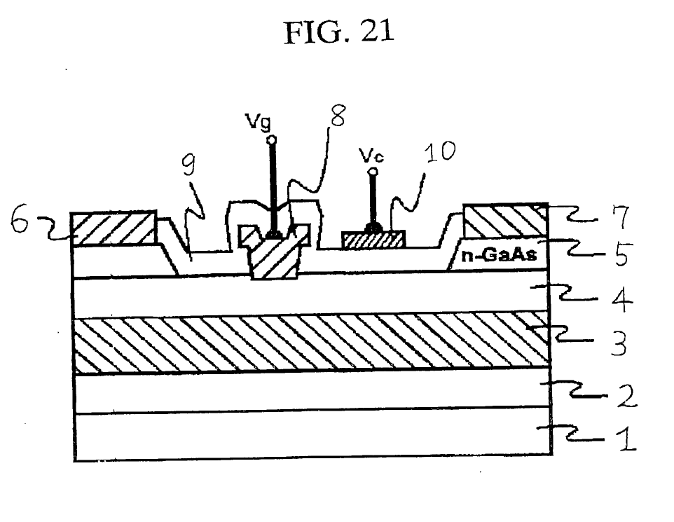

The above described fifth preferred embodiment will be described in more detail to enable a person skilled in the art to practice the invention in accordance with the fifth preferred embodiment. The field effect transistor described with reference to FIG. 5 in the fifth preferred embodiment may be formed as follows and similarly to Example 1 and described in detail with reference to FIGS. 13A through 13G. FIG. 21 is a fragmentary cross sectional elevation view illustrative of the fifth novel field effect transistor of Example 5 according to the present invention. A structural difference of the fifth novel field effect transistor of Example 5 from the first novel field effect transistor of Example 1 is that the field control electrode is electrically isolated even from the gate electrode, so that the field control electrode has an independent potential from the potential of the gate electrode.

With reference to FIG. 21, an AlGaAs buffer layer 2 was deposited by an MOCVD on a semi-insulating GaAs substrate 1. An n-InGaP layer 3, which is Si-doped at a doping concentration of 3E17 cm⁻³ and has a thickness of 150 nanometers, was deposited by the MOCVD on the AlGaAs buffer layer 2. An AlGaAs Schottky layer 4 with a thickness of 20 nanometers was deposited by the MOCVD on the n-InGaP layer 3. An n-GaAs contact layer 5, which is Si-doped at a doping concentration of 3E17 cm⁻³ and has a thickness of 150 nanometers, was deposited by the MOCVD on the AlGaAs Schottky layer 4.

A resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

An SiO₂ insulating film 14 with a thickness of 300 nanometers was deposited by a CVD method over the n-GaAs contact layer 5 and an exposed surface of the AlGaAs Schottky layer 4. The SiO₂ insulating film 14 was then selectively etched by a dry etching process using SF6 to selectively form, in the SiO₂ insulating film 14, a recess, through which a part of the surface of the AlGaAs Schottky layer 4 is exposed.

The AlGaAs Schottky layer 4 was then selectively etched at a shallow depth of approximately 5 nanometers by a dry etching process using the SiO₂ insulating film 14 including the recess as a mask. A WSi film of a thickness of 100 nanometers and an Au film of a thickness of 400 nanometers were sequentially deposited entirely by a sputtering method over the SiO₂ insulating film 14 and the exposed surface of the AlGaAs Schottky layer 4. A resist pattern was selectively formed by a lithography technique over the Au film. The laminations of the WSi film and the Au film were selectively etched by an ion-milling using the resist pattern as a mask, to selectively form a gate electrode 8. The used resist pattern was removed and the SiO₂ insulating film 14 was also removed by a fluorine acid. Another SiO₂ insulating film 9 with a thickness of 100 nanometers was then deposited by the CVD method over the contact layers 5, the exposed surface of the AlGaAs Schottky layer 4 and the gate electrode 8.

A Ti film of a thickness of 100 nanometers and an Au film of a thickness of 500 nanometers were sequentially deposited entirely by a sputtering method over the SiO₂ insulating film 9. A resist pattern was selectively formed by a lithography technique over the Au film. The laminations of the Ti film and the Au film were selectively etched using the resist pattern as a mask, to selectively form a field control electrode 10, which is positioned between the gate electrode 8 and the drain electrode 7, provided that the field control electrode 10 is spatially distanced from them. The used resist pattern was removed.

The SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers. The field effect transistor according to the present invention was completed, wherein a gate width is 1 millimeter.

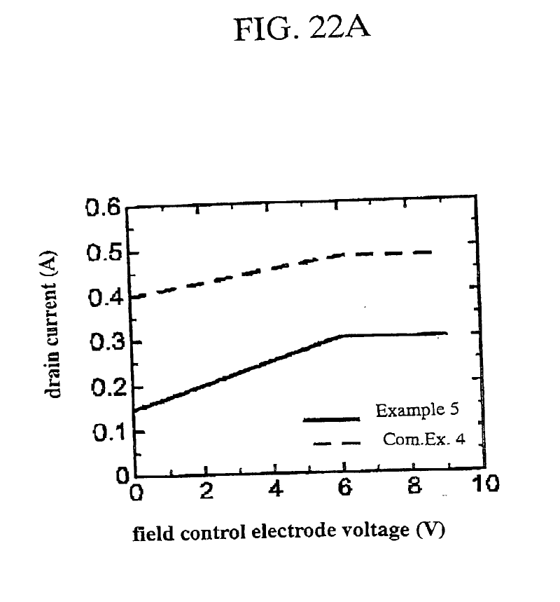

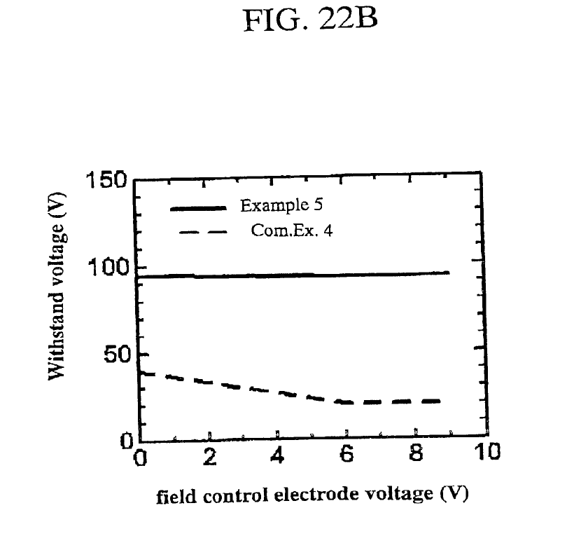

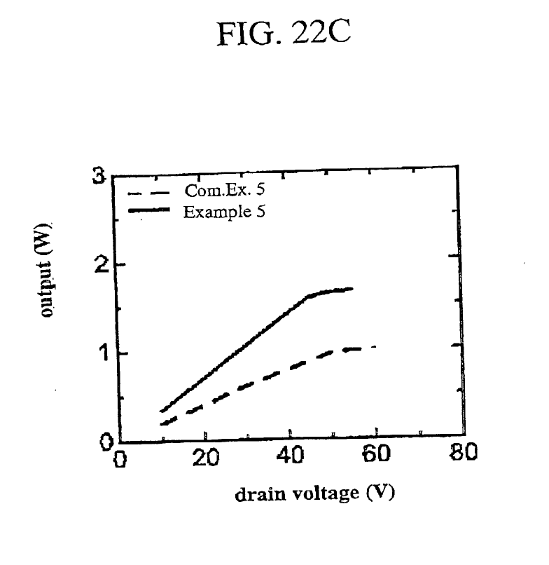

FIG. 22A is a diagram illustrative of respective variations in drain current over a field control electrode voltage of the fifth novel field effect transistor in Example 5 according to the present invention and a fourth conventional field effect transistor as the fourth comparative example. The fourth conventional field effect transistor as the fourth comparative example has the same structure as the conventional field effect transistor shown in FIG. 26, except that the field control electrode 10 is not electrically isolated from the gate electrode 8, so that the field control electrode 10 has an independent potential from the gate electrode 8. In FIG. 22A, the real line represents variation in drain current over the field control electrode voltage of the fifth novel field effect transistor in Example 5 according to the present invention, while the broken line represents variation in drain current over the field control electrode voltage of the fourth conventional field effect transistor in the fourth comparative example.

It was confirmed that the fifth novel field effect transistor of Example 5, which has the electrically floating field control electrode 10 from the gate electrode 8, exhibits almost the same drain current of 0.15A as the field effect transistor free of the field control electrode, provided that the gate width is 1 millimeter. It was also confirmed that when the field control electrode voltage (Vc) is +6V, the fifth novel field effect transistor exhibits the maximum drain current is 0.3A, provided that the gate width is 1 millimeter. Namely, application of the positive voltage (Vc) to the electrically floating field control electrode causes a remarkable increase in the maximum drain current. In contrast, in the fourth conventional field effect transistor as the fourth comparative example, application of the positive voltage (Vc) to the electrically floating field control electrode causes a slight increase in the maximum drain current.

FIG. 22B is a diagram illustrative of respective variations in withstand voltage over field control electrode voltages of the fifth novel field effect transistor in Example 5 according to the present invention and the fourth conventional field effect transistor as the fourth comparative example. In FIG. 22B, the real line represents variation in withstand voltage over the field control electrode voltages of the fifth novel field effect transistor in Example 5 according to the present invention, while the broken line represents variation in withstand voltage over the field control electrode voltage of the fourth conventional field effect transistor in the fourth comparative example.

It was confirmed that the fifth novel field effect transistor of Example 5, which has the electrically floating field control electrode 10 from the gate electrode 8, exhibits almost no variation in the withstand voltage over the field control electrode voltages, while the fourth conventional field effect transistor in the fourth comparative example, which has the electrically floating field control electrode 10 from the gate electrode 8, exhibits a remarkable decrease in the withstand voltage as the field control electrode voltage increases.

FIGS. 22A and 22B demonstrate that the fifth novel field effect transistor of Example 5, which has the electrically floating field control electrode 10 from the gate electrode 8, exhibits the remarkable increase in the maximum drain with almost no decrease in the withstand voltage as the field control electrode voltage increases. This implies that the application to the positive voltage to the field control electrode results in a remarkable increase in the output.

It should be noted that in the conventional transistor disclosed in Japanese laid-open patent publication No. 2000-3919, the negative voltage (Vc) is applied to the control electrode to increase the withstand voltage but never increase the drain current, resulting in no improvement in the high output characteristic.

In accordance with the present invention, InGaP is used to obtain the high withstand voltage characteristic, and further the positive voltage (Vc) is applied to the control electrode to increase the drain current rather than increase the withstand voltage, thereby to obtain both the large drain current and the high withstand voltage, resulting in the high output characteristic.

FIG. 22C is a diagram illustrative of respective variations in output over drain voltages of the fifth novel field effect transistor in Example 5 according to the present invention and a fifth conventional field effect transistor as the fifth comparative example. The fifth conventional field effect transistor as the fifth comparative example has the same structure as shown in FIG. 27. The voltage (Vc) of +6V was applied to the field control electrode 10. In FIG. 22C, the real line represents variation in output over drain voltages of the fifth novel field effect transistor in Example 5 according to the present invention, while the broken line represents variation in output over drain voltages of the fifth conventional field effect transistor in the fifth comparative example.

It was confirmed that the fifth novel field effect transistor of Example 5, which has the electrically floating field control electrode 10 from the gate electrode 8, exhibits a remarkable increase in the output as the drain current increases, while the fifth conventional field effect transistor exhibits a smaller increase in the output as the drain current increases, as compared to the fifth novel field effect transistor of Example 5. In the fifth novel field effect transistor of Example 5, the increase in the drain voltage causes the increase in the DC drain current, thereby increasing the RF current amplitude, resulting in the remarkable increase in the output.

In accordance with the fifth novel field effect transistor of Example 5, the voltage (Vc) is applied to the field control electrode 10 independently from the gate voltage applied to the gate electrode 8. This implies that the application of the large positive voltage to the field control electrode 10 is allowable, unless the large positive voltage is beyond the break down voltage of the insulating film 9. Even if the insulating film 9 is needed to be thick for any process requirement, the application of the sufficiently large positive voltage to the field control electrode 10 controls the space charge region of the channel layer.

The above described effect provided by the electrically floating field control electrode may be obtained by modification to the first, second, third and fourth novel field effect transistors in Examples 1, 2, 3 and 4, so that the field control electrode 10 is electrically isolated from the gate electrode 8 for independent application of the large positive voltage to the field control electrode 10 from the gate voltage applied to the gate electrode 8.

### EXAMPLE 6

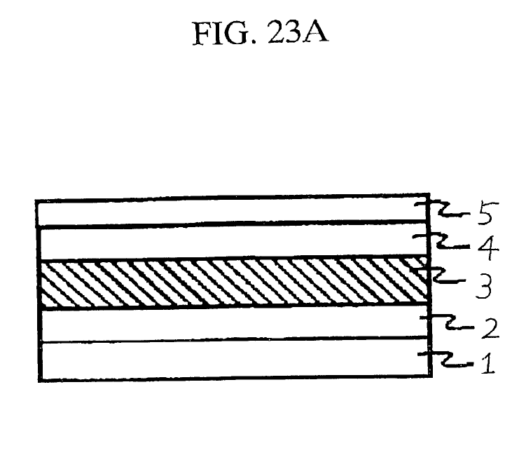

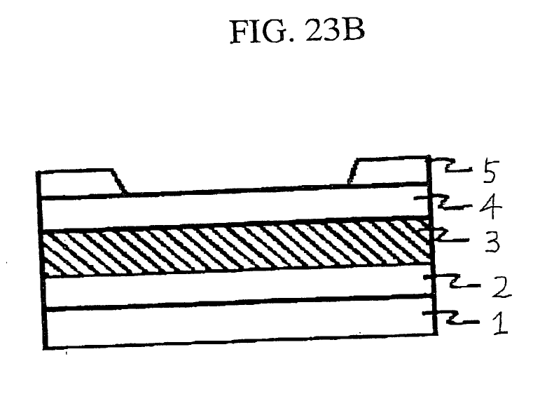

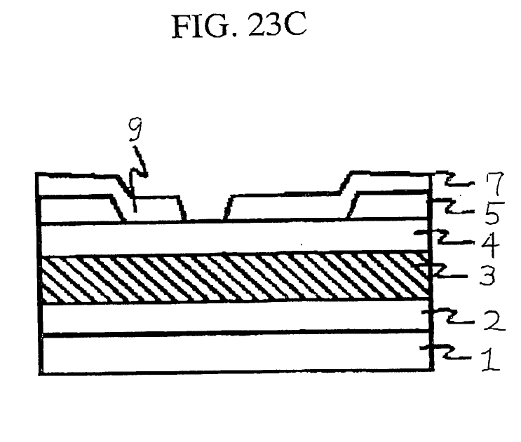

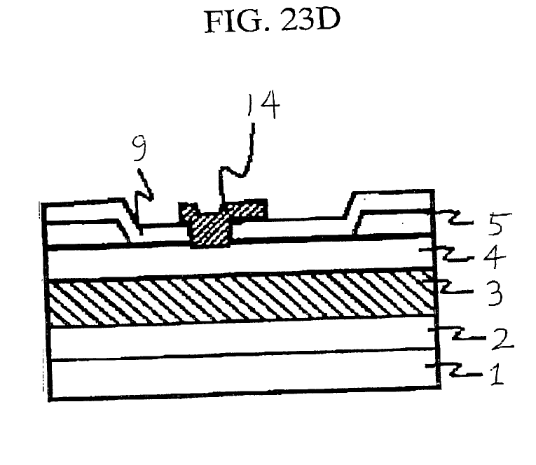

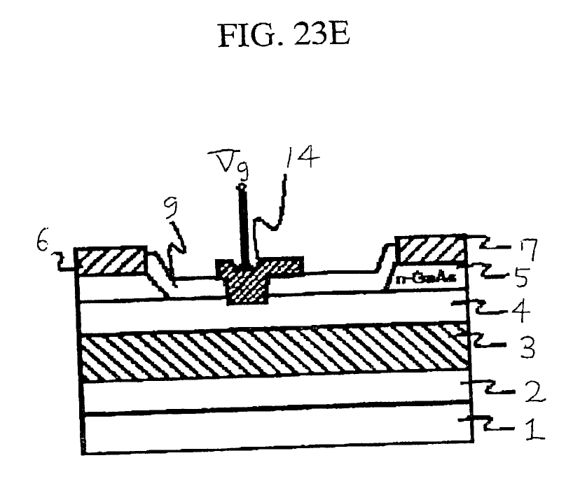

The above described ninth preferred embodiment will be described in more detail to enable a person skilled in the art to practice the invention in accordance with the first preferred embodiment. The field effect transistor described with reference to FIG. 9 in the ninth preferred embodiment may be formed as follows. FIGS. 23A through 23E are fragmentary cross sectional elevation views illustrative of the field effect transistors in sequential steps involved in the novel method in accordance with the present invention.

With reference to FIG. 23A, an AlGaAs buffer layer 2 was deposited by an MOCVD on a semi-insulating GaAs substrate 1. An n-InGaP layer 3, which is Si-doped at a doping concentration of 3E17 cm⁻³ and has a thickness of 150 nanometers, was deposited by the MOCVD on the AlGaAs buffer layer 2. An AlGaAs Schottky layer 4 with a thickness of 20 nanometers was deposited by the MOCVD on the n-InGaP layer 3. An n-GaAs contact layer 5, which is Si-doped at a doping concentration of 3E17 μcm⁻³ and has a thickness of 150 nanometers, was deposited by the MOCVD on the AlGaAs Schottky layer 4.

With reference to FIG. 23B, a resist pattern was formed over the n-GaAs contact layer 5 by a lithography technique. The n-GaAs contact layer 5 was selectively etched by a wet etching process using a sulfuric acid based solution and the resist pattern as a mask to selectively form a recess in the n-GaAs contact layer 5. The used resist pattern was removed.

With reference to FIG. 23C, an SiO₂ insulating film 9 with a thickness of 300 nanometers was deposited by a CVD method over the n-GaAs contact layer 5 and an exposed surface of the AlGaAs Schottky layer 4. The SiO₂ insulating film 9 was then selectively etched by a dry etching process using SF6 to selectively form, in the SiO₂ insulating film 9, a recess, through which a part of the surface of the AlGaAs Schottky layer 4 is exposed.

With reference to FIG. 23D, the AlGaAs Schottky layer 4 was then selectively etched at a shallow depth of approximately 5 nanometers by a dry etching process using the SiO₂ insulating film 9 including the recess as a mask. A WSi film of a thickness of 100 nanometers and an Au film of a thickness of 400 nanometers were sequentially deposited entirely by a sputtering method over the SiO₂ insulating film 9 and the exposed surface of the AlGaAs Schottky layer 4. A resist pattern was selectively formed by a lithography technique over the Au film. The laminations of the WSi film and the Au film were selectively etched by an ion-milling using the resist pattern as a mask, to selectively form a gate electrode 14 which has a drain-side gate extension portion.

With reference to FIG. 23E, the SiO₂ insulating film 9 was selectively etched, so that the surfaces of the contact layers 5 are exposed. Source and drain electrodes 6 and 7 are selectively formed on the exposed surfaces of the contact layers 5 by sequential vacuum-evaporations of an AuGe film of a thickness of 50 nanometers, an Ni film of a thickness of 8 nanometers, and an Au film of a thickness of 250 nanometers. The field effect transistor according to the present invention was completed, wherein a gate width is 1 millimeter.

The above-described drain-side gate extension portion of the gate electrode 14 serves as a field control electrode which is a part of the gate electrode 14. A space charge region under the drain-side gate extension portion serving as the field control electrode is so modulated as tuned with the modulation to the gate electrode 14. An RF-signal is inputted into the gate electrode 8. When the potential of the gate electrode 8 becomes positive, a space charge region under the drain-side gate extension portion serving as the field control electrode becomes small, because the drain current is increased and the current amplitude becomes large in the high output operation to improve the RF-output. Further, reduction to the RF-loss due to the resistive component in the drain side may improve the RF-output. InGaP has a band gap of about 1.9 eV which is larger than a band gap of about 1.4 eV of GaAs. This is advantageous for high voltage operation. The n-InGaP layer 3 improves a high withstand voltage characteristic, while the drain-side gate extension portion serving as the field control electrode improves the large current characteristic. The combination of the n-InGaP layer 3 and the drain-side gate extension portion serving as the field control electrode improves the high output characteristic.

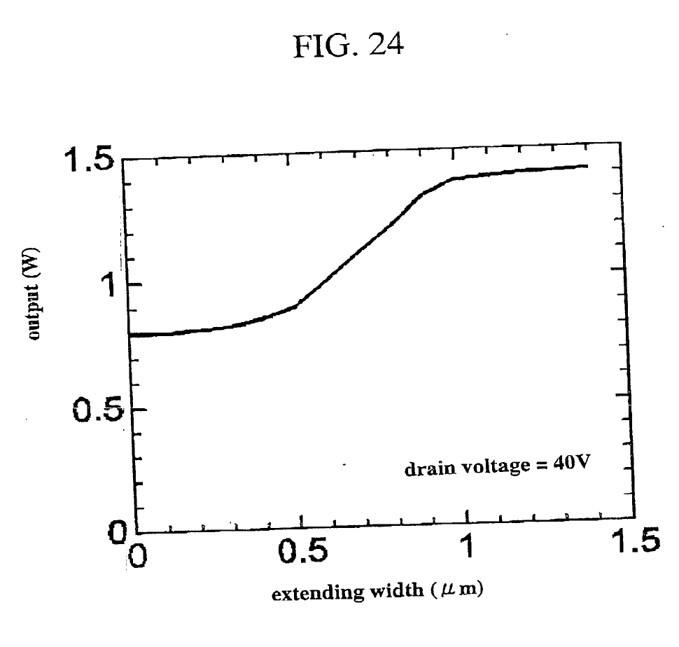

A relationship of the extending width, or a lateral size, of the drain-side gate extension portion of the gate electrode 14 and the obtained output at a frequency of 2 GHz and a drain voltage of 40V was investigated. FIG. 24 is a diagram illustrative of variations in the output over the extending width, or the lateral size, of the drain-side gate extension portion of the gate electrode of the sixth novel field effect transistor of Example 6 according to the present invention.

It was confirmed that as the extending width increases from 0.5 micrometers to 1 micrometer, the obtained output also increases. As the extending width is beyond 1 micrometer, the obtained output remains high. This demonstrates that the extending width of the drain-side gate extension portion of the gate electrode is preferably not less than 0.5 micrometers and more preferably 1 micrometer, provided that an expensively large extending width increases the gate capacity. In view of both obtaining a possible high output and suppressing the increase in the capacity of the gate electrode, the extending width of the drain-side gate extension portion of the gate electrode is most preferably in the range of about 1 micrometer to 2 micrometers.

The above-described effects of the sixth novel field effect transistor of Example 6 may be obtained by modifications to the first, second, third and fourth novel field effect transistors of Examples 1, 2, 3 and 4, according to the present invention, so that the field control electrode comprises the drain-side gate extension portion of the gate electrode.

Although the invention has been described above in connection with several preferred embodiments therefor, it will be appreciated that those embodiments have been provided solely for illustrating the invention, and not in a limiting sense. Numerous modifications and substitutions of equivalent materials and techniques will be readily apparent to those skilled in the art after reading the present application, and all such modifications and substitutions are expressly understood to fall within the true scope and spirit of the appended claims.

What is claimed is:

1. A field effect transistor including:
a substrate;
a channel layer over said substrate, and said channel layer comprising a first compound semiconductor having a larger band gap than GaAs
a Schottky layer over said channel layer;
a gate electrode having a Schottky junction with said Schottky layer;
source and drain electrodes spatially distanced from each other and also from said gate electrode;
an insulating layer extending over at least a first region of said Schottky layer, and said first region being positioned between said gate electrode and said drain electrode; and
a field control electrode extending over said insulating layer and being separated from said Schottky layer, and said field control electrode being positioned between said gate electrode and said drain electrode for controlling a space charge region in said channel layer and under said at least first region.

2. The field effect transistor as claimed in claim 1, wherein said field control electrode is spatially distanced from and electrically isolated from said drain electrode.

3. The field effect transistor as claimed in claim 2, wherein said field control electrode is spatially distanced from and electrically isolated from said gate electrode, so that said field control electrode is independent in potential from said gate electrode.

4. The field effect transistor as claimed in claim 2, wherein said field control electrode is spatially distanced from and electrically coupled to said gate electrode, so that said field control electrode is dependent in potential on said gate electrode.

5. The field effect transistor as claimed in claim 2, wherein said field control electrode comprises an extension portion of said gate electrode, and said extension portion extends from said gate electrode toward said drain electrode, so that said field control electrode depends in potential on said gate electrode.

6. The field effect transistor as claimed in claim 5, wherein said extension portion has a horizontal size in a range of 0.5 micrometer to 2 micrometers in a direction parallel to a line connecting between said gate electrode and said drain electrode.

7. The field effect transistor as claimed in claim 2, wherein said field control electrode is applied with a positive DC-voltage.

8. The field effect transistor as claimed in claim 2, wherein said first compound semiconductor of said channel layer is InGaP.

9. The field effect transistor as claimed in claim 8, wherein said Schottky layer comprises an InGaP layer comprises an InGaP layer.

10. The field effect transistor as claimed in claim 8, wherein said Schottky layer comprises an InGaP layer comprises a strained InGaP layer.

11. The field effect transistor as claimed in claim 8, wherein said Schottky layer comprises an InGaP layer comprises an InAlGaP layer.

12. The field effect transistor as claimed in claim 2, wherein said substrate comprises a GaAs substrate.

13. A semiconductor device including:
a substrate;
a channel layer over said substrate, and said channel layer comprising a first compound semiconductor having a larger band gap than GaAs;
a Schottky layer over said channel layer;
a gate electrode having a Schottky junction with said Schottky layer
source and drain electrodes spatially distanced from each other and also from said gate electrode; and
a field controller for controlling an expansion of a space charge region in said channel layer and between said gate electrode and said drain electrode.

14. The semiconductor device as claimed in claim 13, wherein said field controller comprises a field control electrode electrically isolated by an insulating film from said Schottky layer, and being positioned between said gate electrode and said drain electrode.

15. The semiconductor device as claimed in claim 14, wherein said field control electrode is spatially distanced from and electrically isolated from said drain electrode.

16. The semiconductor device as claimed in claim 15, wherein said field control electrode is spatially distanced from and electrically isolated from said gate electrode, so that said field control electrode is independent in potential from said gate electrode.

17. The semiconductor device as claimed in claim 15, wherein said field control electrode is spatially distanced from and electrically coupled to said gate electrode, so that said field control electrode is dependent in potential on said gate electrode.

18. The semiconductor device as claimed in claim 15, wherein said field control electrode comprises an extension portion of said gate electrode, and said extension portion extends from said gate electrode toward said drain electrode, so that said field control electrode depends in potential on said gate electrode.

19. The semiconductor device as claimed in claim 18, wherein said extension portion has a horizontal size in a range of 0.5 micrometer to 2 micrometers in a direction parallel to a line connecting between said gate electrode and said drain electrode.

20. The semiconductor device as claimed in claim 15, wherein said field control electrode is applied with a positive DC-voltage.

21. The semiconductor device as claimed in claim 15, wherein said first compound semiconductor of said channel layer is InGaP.

22. The semiconductor device as claimed in claim 21, wherein said Schottky layer comprises an InGaP layer comprises an InGaP layer.

23. The semiconductor device as claimed in claim 21, wherein said Schottky layer comprises an InGaP layer comprises a strained InGaP layer.

24. The semiconductor device as claimed in claim 21, wherein said Schottky layer comprises an InGaP layer comprises an InAlGaP layer.

25. The semiconductor device as claimed in claim 14, wherein said substrate comprises a GaAs substrate.

26. A field effect transistor including:
a GaAs substrate;
an InGaP channel layer over said GaAs substrate;
a Schottky layer over said InGaP channel layer;
a gate electrode having a Schottky junction with said Schottky layer
source and drain electrodes spatially distanced from each other and also from said gate electrode;
an insulating layer extending over said Schottky layer; and
a field control electrode extending over said insulating layer and being separated from said Schottky layer by said insulating layer, and said field control electrode being positioned between said gate electrode and said drain electrode, and said field control electrode being spatially separated from said gate electrode and from said drain electrode, and said field control electrode being electrically coupled to said gate electrode, so that said field control electrode depends in potential on said gate electrode, said field control electrode being applied with a positive voltage for controlling an expansion of a space charge region in said channel layer between said gate electrode and said drain electrode.

27. A field effect transistor including:
a GaAs substrate;
an InGaP channel layer over said GaAs substrate;
a Schottky layer over said InGaP channel layer;
a gate electrode having a Schottky junction with said Schottky layer;
source and drain electrodes spatially distanced from each other and also from said gate electrode;
an insulating layer extending over said Schottky layer; and
a field control electrode extending over said insulating layer and being separated from said Schottky layer by said insulating layer, and said field control electrode being positioned between said gate electrode and said drain electrode, and said field control electrode being spatially separated from said gate electrode and from said drain electrode, and said field control electrode being electrically isolated from said gate electrode, so that said field control electrode is independent in potential from said gate electrode, said field control electrode being applied with a positive voltage for controlling an expansion of a space charge region in said channel layer between said gate electrode and said drain electrode.

28. A field effect transistor including:
a GaAs substrate;
an InGaP channel layer over said GaAs substrate;
a Schottky layer over said InGaP channel layer;
a gate electrode having a Schottky junction with said Schottky layer;
source and drain electrodes spatially distanced from each other and also from said gate electrode; and
an insulating layer extending over said Schottky layer;
wherein said gate electrode includes an extension portion which extends over said insulating layer toward said drain electrode, and said extension portion being separated from said Schottky layer by said insulating layer and also spatially separated from said drain electrode, and said extension portion controlling an expansion of a space charge region in said channel layer between said gate electrode and said drain electrode.
